(19) United States
(12) Patent Application Publication
(10) Pub. No.: US 2024/0404977 A1
(43) Pub. Date: Dec. 5, 2024

(54) SEMICONDUCTOR DEVICE AND SEMICONDUCTOR MODULE

(71) Applicant: ROHM CO., LTD., Kyoto-shi (JP)

(72) Inventor: Kazunori FUJI, Kyoto-shi (JP)

(21) Appl. No.: 18/804,601

(22) Filed: Aug. 14, 2024

Related U.S. Application Data
(63) Continuation of application No. PCT/JP2023/004560, filed on Feb. 10, 2023.

(30) Foreign Application Priority Data
Feb. 24, 2022 (JP) 2022-027147

(51) Int. Cl. H01L 23/00; H01L 23/31; H01L 23/36; H01L 25/065

(52) U.S. Cl. CPC H01L 24/24; H01L 23/3185; H01L 23/36; H01L 25/0655; H01L 24/32; H01L 24/73; H01L 2224/2405; H01L 2224/24137; H01L 2224/32245; H01L 2224/73217

(57) ABSTRACT

A semiconductor device includes a first semiconductor element with a first gate electrode, a second semiconductor element with a second gate electrode, a sealing resin, a first signal terminal with a third center, and a first signal wiring. The first line connecting the first center of the first gate electrode and the third center has a first line length L1. The second line connecting the second center of the second gate electrode and the third center has a second line length L2. The path from the first center to the third center via the first signal wiring has a first path length R1. The path from the second center to the third center via the first signal wiring has a second path length R2. In the semiconductor device, R2/R1 is closer to 1 than is L2/L1.

### TECHNICAL FIELD

The present disclosure relates to a semiconductor device and a semiconductor module.

### BACKGROUND ART

Conventionally, semiconductor modules with multiple semiconductor elements with switching functions mounted therein are known. The semiconductor modules are mainly used for power conversion. JP-A-2013-258387 discloses an example of such a semiconductor module.

Each of the semiconductor elements mounted in the semiconductor module disclosed in JP-A-2013-258387 has a source electrode and a drain electrode that are located on opposite sides to each other. A top plate electrode is conductively bonded to the source electrode, and a drain conductively bonded to the drain electrode pattern is electrode. Each semiconductor element is sandwiched between the top plate electrode and the drain electrode pattern. This configuration may make it possible to reduce parasitic resistance in the semiconductor module while also reducing the size of the semiconductor module. The gate voltage applied to each semiconductor element varies depending on the length of the conductive path from the signal terminal to the gate electrode. Hence, in the semiconductor module disclosed in JP-A-2013-258387, which includes only a single signal terminal, there may occur undesired variations in the gate voltages applied to the respective semiconductor elements. Unfavorably, variations of gate voltage may cause delay in the switching operation of the semiconductor elements.

### BRIEF DESCRIPTION OF THE DRAWINGS

FIG. 1 is a plan view of a semiconductor device according to a first embodiment of the present disclosure.

FIG. 2 is a bottom view of the semiconductor device shown in FIG. 1.

FIG. 3 is a cross-sectional view along the III-III line in FIG. 1.

FIG. 4 is a cross-sectional view along the IV-IV line in FIG. 1.

FIG. 5 is a cross-sectional view along the V-V line in FIG. 1.

FIG. 6A is a cross-sectional view along the VIA-VIA line in FIG. 1.

FIG. 6B is a cross-sectional view along the VIB-VIB line in FIG. 1.

FIG. 7 is a plan view of a semiconductor device according to a second embodiment of the present disclosure.

FIG. 8 is a bottom view of the semiconductor device shown in FIG. 7.

FIG. 9 is a cross-sectional view along the IX-IX line in FIG. 7.

FIG. 10 is a cross-sectional view along the X-X line in FIG. 7.

FIG. 11 is a ross-sectional view along the XI-XI line of FIG. 7.

FIG. 12 is a cross-sectional view of a semiconductor device according to a third embodiment of the present disclosure, showing a first semiconductor element and its vicinity.

FIG. 13 is a cross-sectional view of the semiconductor device shown in FIG. 12, showing a second semiconductor element and its vicinity.

FIG. 14 is a cross-sectional view of the semiconductor device shown in FIG. 12, where the cross-sectional location differs from that in FIGS. 12 and 13.

FIG. 15 is a plan view of a semiconductor device according to a fourth embodiment of the present disclosure.

FIG. 16 is a bottom view of the semiconductor device shown in FIG. 15.

FIG. 17 is a cross-sectional view along the XVII-XVII line in FIG. 15.

FIG. 18 is a cross-sectional view along the XVIII-XVIII line in FIG. 15.

FIG. 19 is a cross-sectional view along the XIX-XIX line in FIG. 15.

FIG. 20 is a bottom view of a semiconductor device according to a variation of the fourth embodiment of the present disclosure.

FIG. 21 is a cross-sectional view of the semiconductor device shown in FIG. 20.

FIG. 22 is a plan view of a semiconductor module according to an embodiment of the present disclosure, showing the sealing resin transparently.

FIG. 23 is a plan view corresponding to FIG. 22, showing the conductive member transparently.

FIG. 24 is a bottom view of the semiconductor module shown in FIG. 22.

FIG. 25 is a cross-sectional view along the XXV-XXV line in FIG. 22.

FIG. 26 is a cross-sectional view along the XXVI-XXVI line in FIG. 22.

FIG. 27 is a cross section along line XXVII-XXVII in FIG. 22.

FIG. 28 is a partially enlarged view of FIG. 25, showing the semiconductor device shown in FIG. 1 and its vicinity.

FIG. 29 is a partially enlarged view of FIG. 25, showing the semiconductor device shown in FIG. 7 and its vicinity.

### DETAILED DESCRIPTION OF EMBODIMENTS

Embodiments for carrying out the present disclosure will be described below with reference to the accompanying drawings.

### First Embodiment

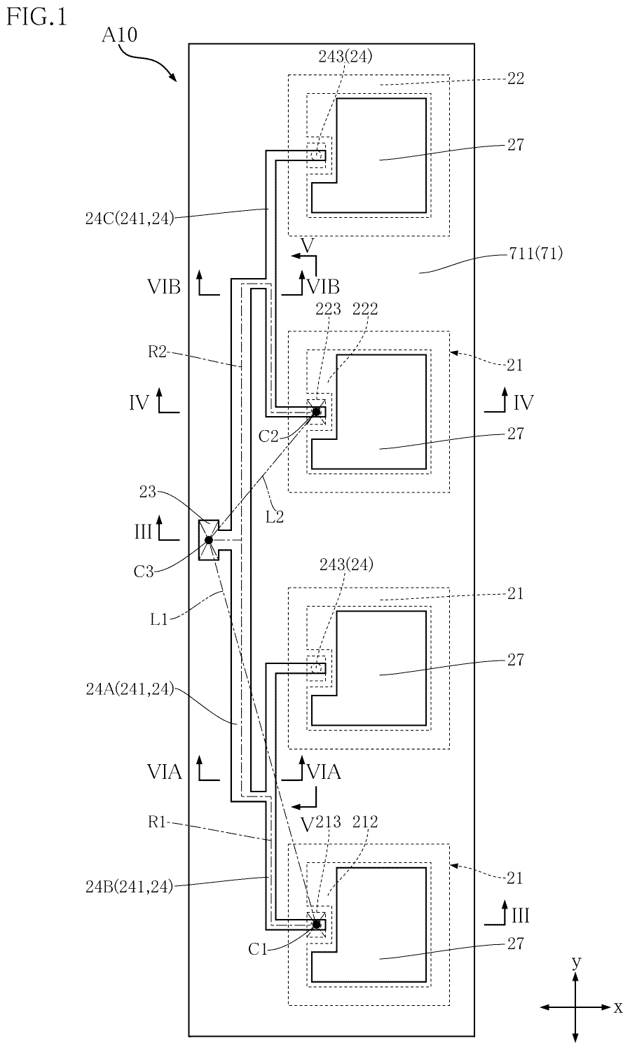

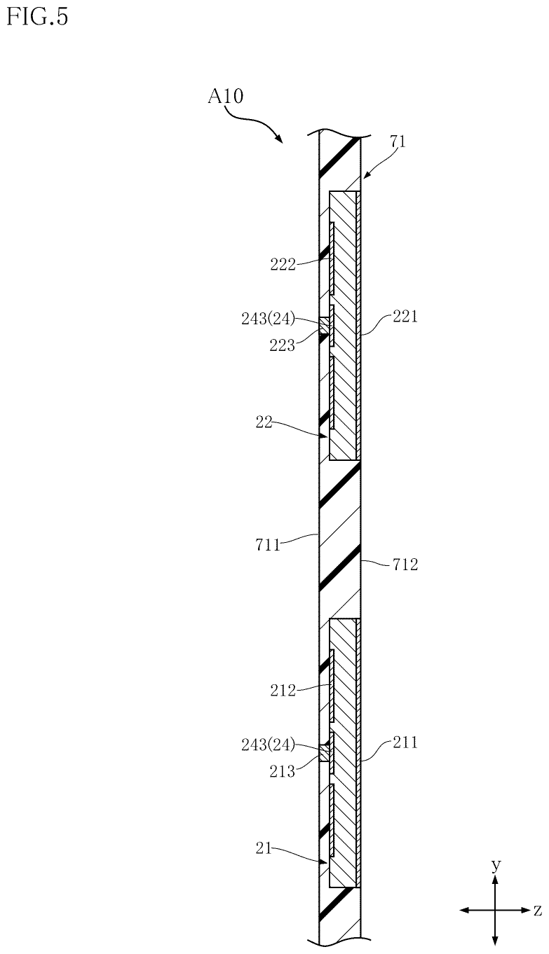

A semiconductor device A10 of a first embodiment of the present disclosure is described based on FIGS. 1 through 6B.

The semiconductor device A10 has two first semiconductor elements 21, two second semiconductor elements 22, a first signal terminal 23, a first signal wiring 24, four top terminals 27, and a sealing resin 71. In FIG. 1, the III-III line is shown as a single dotted line.

In the description of the semiconductor device A10, for convenience, the normal direction of the top surface 711 of the sealing resin 71, which will be described later, is referred to as the “first direction z”. A direction orthogonal to the first direction z is called the “second direction y”. The direction orthogonal to the first direction z and the second direction y is called the “third direction x”.

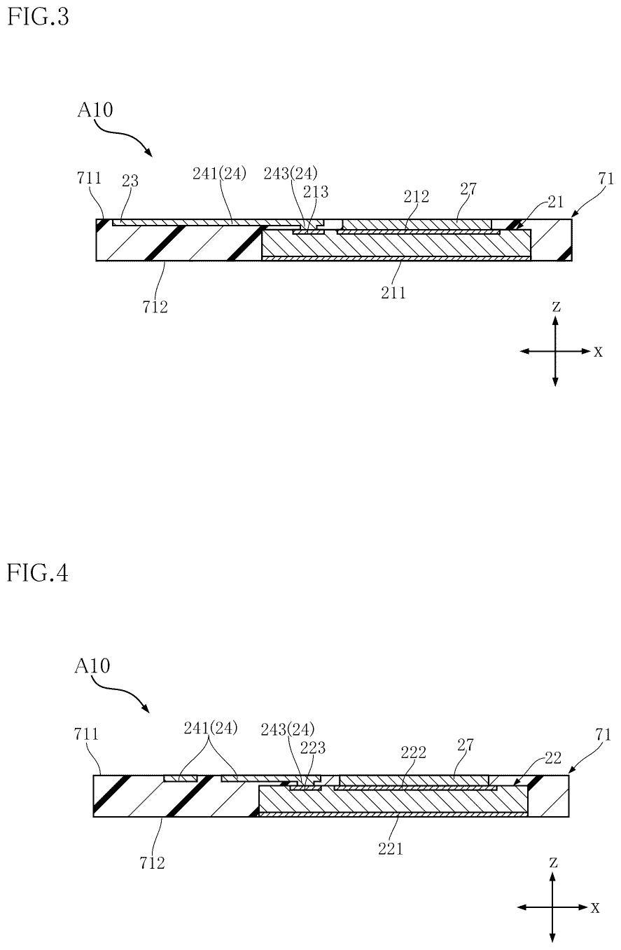

The sealing resin 71 covers at least a portion of each of the two first semiconductor elements 21 and at least a portion of each of the two second semiconductor elements 22, as shown in FIGS. 3 to 5. The sealing resin 71 has a top surface 711 and a bottom surface 712. The top surface 711 and the bottom surface 712 face opposite from each other in the first direction z.

The two first semiconductor elements 21 are arranged side by side to each other in the second direction y, as shown in FIG. 1. The two first semiconductor elements 21 are, for example, MOSFETs (Metal-Oxide-Semiconductor Field-Effect Transistors). Alternatively, the two first semiconductor elements 21 may be field-effect transistors, including MISFETS (Metal-Insulator-Semiconductor Field-Effect Transistors) or bipolar transistors, including IGBTs (Insulated Gate Bipolar Transistors). In the description of below, the two first the semiconductor device A10 semiconductor elements 21 are MOSFETs that are n-channel type and have a vertical structure. The two first semiconductor elements 21 include compound semiconductor substrates. The composition of the compound semiconductor substrates may include silicon carbide (Sic).

As shown in FIG. 3, the two first semiconductor elements 21 each have a first electrode 211, a second electrode 212, and a first gate electrode 213.

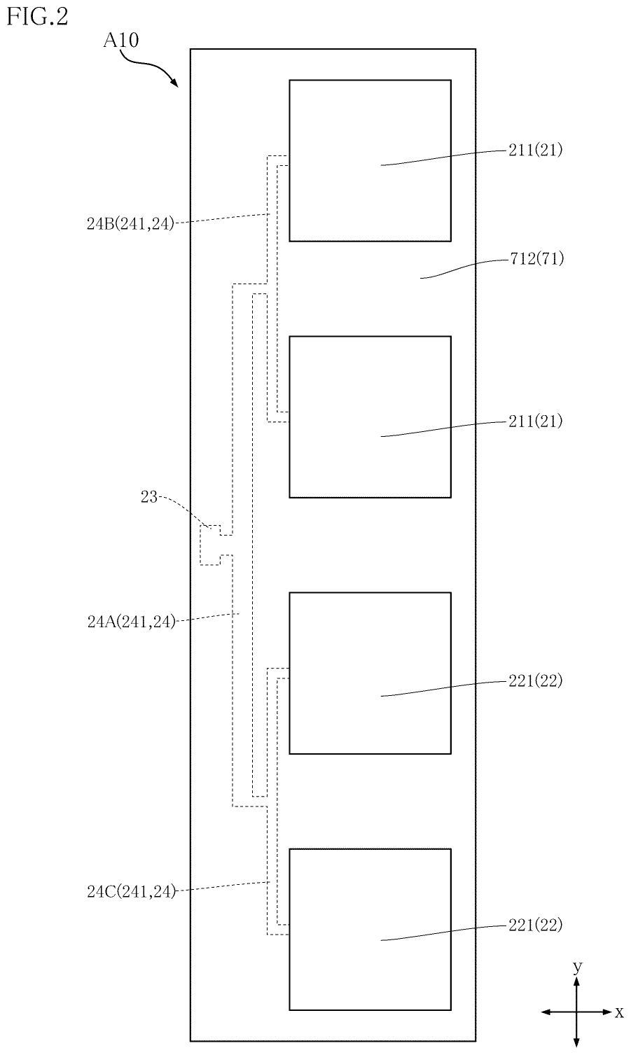

As shown in FIGS. 2 and 3, the first electrode 211 is exposed externally from the bottom surface 712 of the sealing resin 71. A current corresponding to the electric power before it is converted by the first semiconductor element 21 flows through the first electrode 211. Thus, the first electrode 211 may correspond to a drain electrode of the first semiconductor element 21.

As shown in FIG. 3, the second electrode 212 is located opposite to the first electrode 211 in the first direction z. A current corresponding to the electric power after conversion by the semiconductor element 21 flows to the second electrode 212. Thus, the second electrode 212 may correspond to a source electrode of the first semiconductor element 21.

As shown in FIG. 3, the first gate electrode 213 is located opposite to the first electrode 211 in the first direction z. Thus, the first gate electrode 213 is located on the same side as the second electrode 212 in the first direction z. A gate voltage is applied to the first gate electrode 213 for driving the first semiconductor element 21. As shown in FIG. 1, the first gate electrode 213 is rectangular as viewed in the first direction z. Further, as viewed in the first direction z, the first gate electrode 213 has a first center C1. The first center C1 is the intersection of the diagonals of the first gate electrode 213.

The two second semiconductor elements 22 are located opposite to the two first semiconductor elements 21 with respect to the first signal terminal 23 in the second direction y, as shown in FIG. 1. The two second semiconductor elements 22 are arranged side by side to each other in the second direction y. The two second semiconductor elements 22 may be identical in type to the two first semiconductor elements 21. Thus, the two second semiconductor elements 22 may be MOSFETs of n-channel type and having a vertical structure.

As shown in FIG. 4, the two second semiconductor 22 each have a third electrode 221, a fourth elements electrode 222, and a second gate electrode 223.

As shown in FIGS. 2 and 4, the third electrode 221 is located on the same side as the first electrode 211 with respect to the two first semiconductor elements 21 in the first direction z. The third electrode 221 is exposed externally from the bottom 712 of the sealing resin 71. A current corresponding to the power before it is converted by the second semiconductor element 22 flows through the third electrode 221. Thus, the third electrode 221 may correspond to a drain electrode of the second semiconductor element 22.

As shown in FIG. 4, the fourth electrode 222 is located opposite to the third electrode 221 in the first direction z. A current corresponding to the power after conversion by the second semiconductor element 22 flows through the fourth electrode 222. Thus, the fourth electrode 222 may correspond to a source electrode of the second semiconductor element 22.

As shown in FIG. 4, the second gate electrode 223 is located opposite to the third electrode 221 in the first direction z. Thus, the second gate electrode 223 is located on the same side as the fourth electrode 222 in the first direction z. A gate voltage is applied to the second gate electrode 223 for driving the second semiconductor element 22. As shown in FIG. 1, the second gate electrode 223 is rectangular as viewed in the first direction z. Further, as viewed in the first direction z, the second gate electrode 223 has a second center C2. The second center C2 is the intersection of the diagonals of the second gate electrode 223.

The first signal terminal 23 is exposed externally from the top surface 711 of the sealing resin 71, as shown in FIGS. 1 and 3. In the semiconductor device A10, the first signal terminal 23 is located opposite to the first electrode 211 with respect to the two first semiconductor elements 21 in the first direction z. As shown in FIG. 1, the first signal terminal 23 is rectangular as viewed in the first direction z. Further, the first signal terminal 23 has a third center C3 as viewed in the first direction z. The third center C3 is the intersection of the diagonals of the first signal terminal 23.

The first signal wiring 24 is configured to electrically connect the electrode first gate 213 of each first semiconductor element 21 and the second gate electrode 223 of each second semiconductor element 22 to the first signal terminal 23. At least a portion of the first signal wiring 24 is covered by the sealing resin 71.

As shown in FIGS. 1 and 3 through 5, the first signal wiring 24 has a first top portion 241 and first via portions 243. The first top portion 241 is exposed externally from the top surface 711 of the sealing resin 71. The first via portions 243 are covered by the sealing resin 71 . . . the semiconductor device A10, each first via portion 243 is connected to the first top portion 241, while also being connected to the first gate electrode 213 of the relevant first semiconductor element 21 or to the second gate electrode 223 of the relevant second semiconductor element 22.

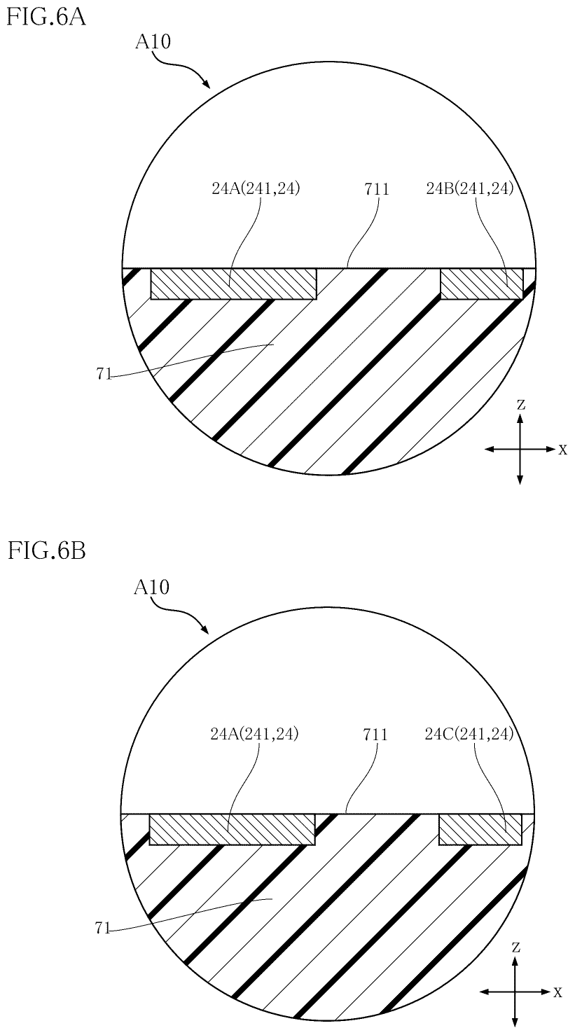

As shown in FIG. 1, the first signal wiring 24 has a first wiring 24A, a second wiring 24B, and a third wiring 24C. The first wiring 24A extends in the second direction y and also conducts to the first signal terminal 23. The second wiring 24B is connected to the first wiring 24A and to the first gate electrodes 213 of the two first semiconductor elements 21. The third wiring 24C is connected to the first wiring 24A and to the second gate electrodes 213 of the two second semiconductor elements 21. As shown in FIG. 6A, the cross-sectional area of the first wiring 24A, which is perpendicular to the second direction y, is larger than the cross-sectional area of the second wiring 24B, which is perpendicular to a direction in which the second wiring 24B extends. As shown in FIG. 6B, the cross-sectional area of the first wiring 24A, which is perpendicular to the second direction y, is larger than the cross-sectional area of the third wiring 24C, which is perpendicular to a direction in which the third wiring 24C extends.

A first linear length L1, a second linear length L2, a first path length R1 and a second path length R2 are defined as follows.

The first linear length L1 is the shortest distance between the first center C1 of the first gate electrode 213 of one of the two first semiconductor elements 21 and the third center C3 of the first signal terminal 23. The second linear length L2 is the shortest distance between the second center C2 of the second gate electrode 223 of one of the two second semiconductor elements 22 and the third center C3. The first path length R1 is the shortest distance (journey) from the first center C1 to the third center C3 via the first signal wiring 24. The second path length R2 is the shortest distance (journey) from the second center C2 to the third center C3 via the first signal wiring 24. In the semiconductor device A10, the value of the second path length R2 divided by the first path length R1 (R2/R1) is closer to 1 than is the value of the second linear length L2 divided by the first linear length L1 (L2/L1).

The first path length R1 may be equal to the second path length R2. Alternatively, the first path length R1 may be not smaller than 85% and not greater than 115% of the second path length R2.

The four top terminals 27 individually contact and conduct to the second electrode 212 of the relevant first semiconductor element 21 or the fourth electrode 222 of the relevant second semiconductor element 22, as shown in FIGS. 1, 3 and 4. The four top terminals 27 are spaced apart from the first gate electrode 213 of the relevant first semiconductor element 21 or the second gate electrode 223 of the relevant second semiconductor element 22. The four top terminals 27 are exposed externally from the top surface 711 of the sealing resin 71.

The first signal terminal 23, the first signal wiring 24, and the four top terminals 27 can be formed by the LDS (Laser Direct Structuring) method disclosed in U.S. Patent Application Publication No. 2010/0019370, for example.

Next, effects and advantages of the semiconductor device A10 will be described.

The semiconductor device A10 includes a first semiconductor element 21, a second semiconductor element 22, a first signal terminal 23, a first signal wiring 24, and a sealing resin 71. The first semiconductor element 21 has a first electrode 211, a second electrode 212, and a first gate electrode 213. The second semiconductor element 22 has a third electrode 221, a fourth electrode 222, and a second gate electrode 223. Definitions are made such that a first linear length L1 is to connect the first center C1 of the first gate electrode 213 and the third center C3 of the first signal terminal 23, and a second linear length L2 is to connect the second center C2 of the second gate electrode 223 and the third center C3. Further, a first path length R1 is defined as the length from the first center C1 to the third center C3 via the first signal wiring 24, and a second path length R2 is defined as the length from the second center C2 to the third center C3 via the first signal wiring 24. With the semiconductor device A10, the value of the second path length R2/the first path length R1 is closer to 1 than is the second linear length L2/the first linear length L1 (see FIG. 1). With this configuration, the second path length R2 is equal (or substantially equal) to the first path length R1. Thus, when a gate voltage is applied to the first signal terminal 23, the current flowing to the second gate electrode 223 is equal (or substantially equal) to the current flowing to the first gate electrode 213. Accordingly, by the semiconductor device A10, it is possible to achieve application of uniform gate voltage to each of the multiple semiconductor elements.

Further, the first signal wiring 24 includes a first wiring 24A and a second wiring 24B. The first wiring 24A extends in the second direction y and is connected to the first signal terminal 23. The second wiring 24B is connected to the first wiring 24A and the first gate electrode 213. The cross-sectional area of the first wiring 24A, which is perpendicular to the second direction y, is larger than the cross-sectional area of the second wiring 24B, which is perpendicular to the direction in which the second wiring 24B extends. Note that the sum of the currents flowing to the first gate electrodes 213 of the two first semiconductor elements 21 flows to the first wiring 24A. With the configuration of the present disclosure, the loss of current flowing in the first signal wiring 24 can be efficiently suppressed.

The first signal terminal 23 is located opposite to the first electrode 211 with respect to the first semiconductor elements 21 in the first direction z. With this configuration, when the first electrode 211 is conductively bonded to a conductive member in mounting the semiconductor device A10, the first signal terminal 23 is located opposite to the side that faces the conductive member in the first direction z. Thus, it is advantageously easy to conductively bond wires or other elements to the first signal terminal 23.

The semiconductor device A10 further includes a top terminal 27 spaced apart from the first gate electrode 213 and held in contact with the second electrode 212. The top terminal 27 is exposed externally from the sealing resin 71. This configuration allows easy external conduction of the second electrode 212, while the first signal terminal 23 and the first signal wiring 24 are formed.

### Second Embodiment

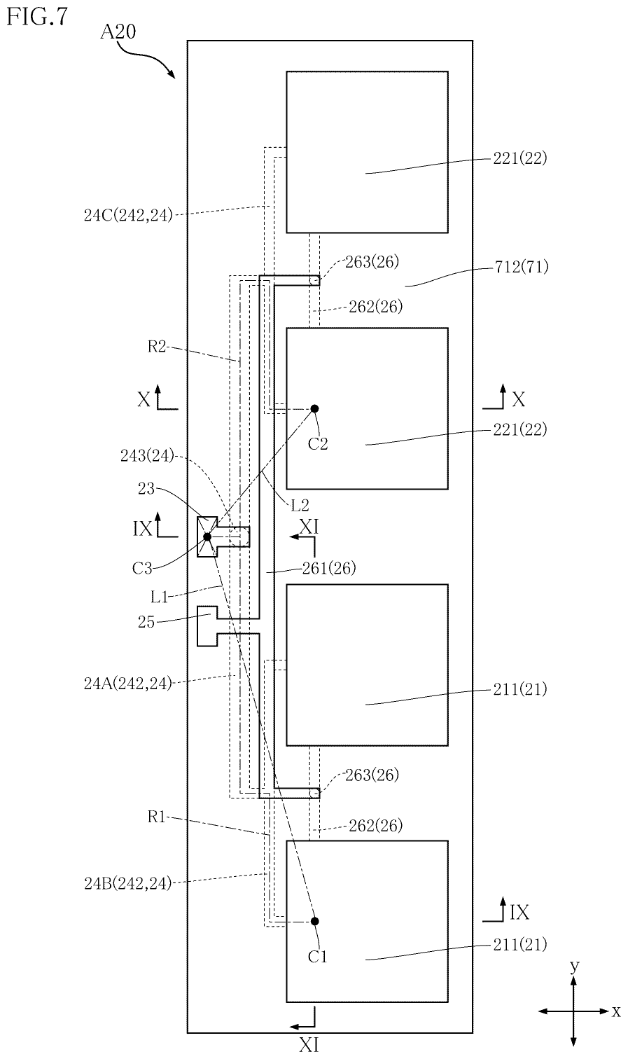

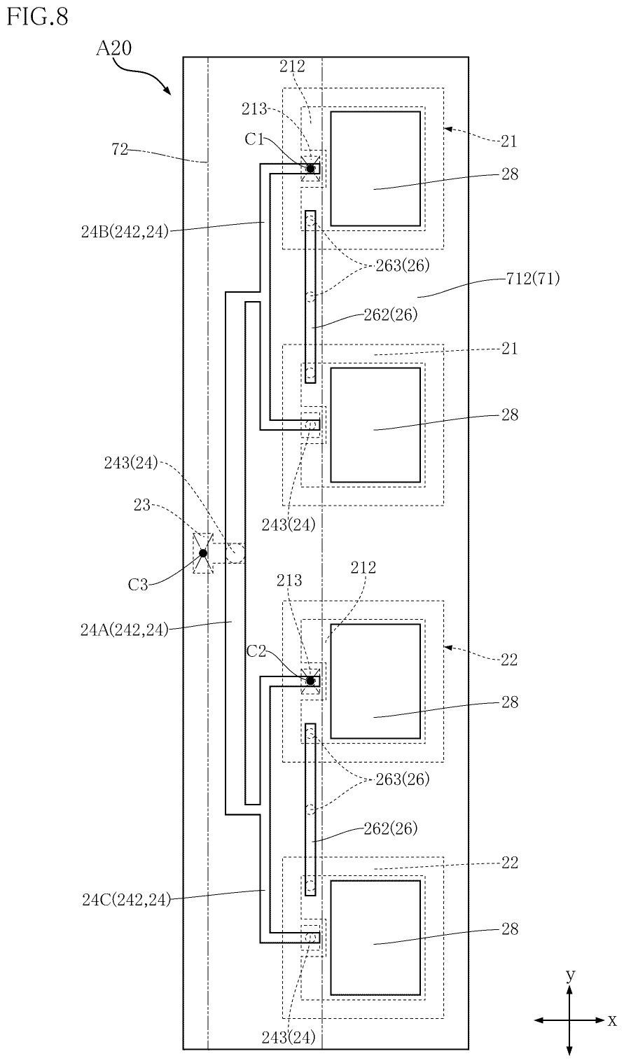

A semiconductor device A20 according to a second embodiment of the present disclosure is described below based on FIGS. 7 to 11. In these figures, the same or similar elements to those of the previously described semiconductor device A10 are indicated by the same symbols, and redundant explanations are omitted. In FIG. 8, the coating layer 72 is shown through for convenience of understanding, and the outline of the coating layer 72 is shown as an imaginary line (double-dashed line).

In the semiconductor device A20, the configuration of the first signal terminal 23 and the first signal wiring 24 differs from that of the semiconductor device A10. The semiconductor device A20 further includes a second signal terminal 25, a second signal wiring 26, a bottom terminal 28, and a coating layer 72 with respect to the semiconductor device A10. Unlike the semiconductor device A10, the semiconductor device A20 does not have top terminals 27.

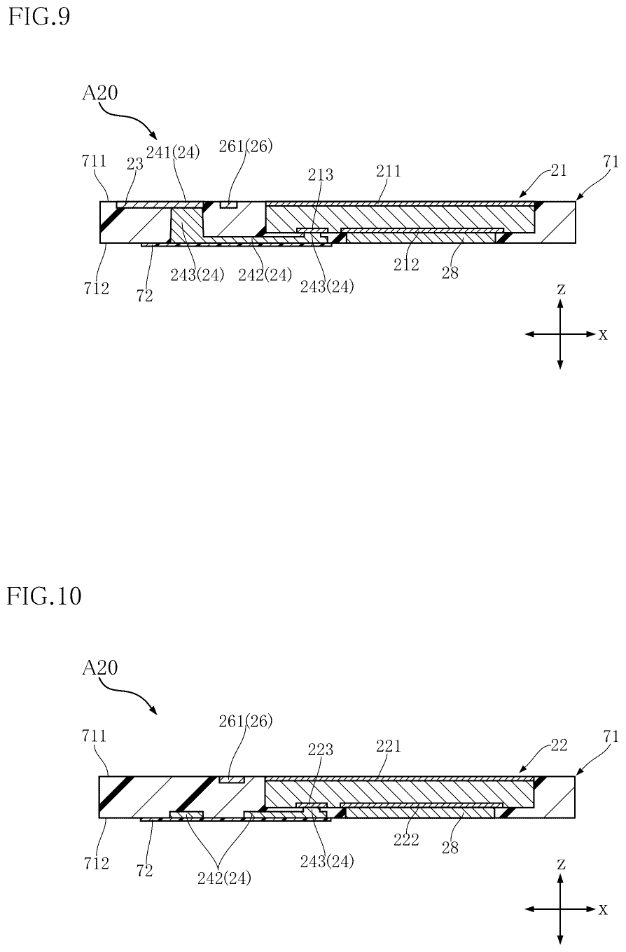

As shown in FIGS. 7 and 9, the first signal terminal 23 is located opposite to the second electrode 212 with respect to the two first semiconductor elements 21 in the first direction z.

As shown in FIGS. 7 through 11, the first signal wiring 24 further includes a first bottom portion 242. The first bottom portion 242 is exposed from the bottom surface 712 of the sealing resin 71. In the semiconductor device A20, the first via portions 243 are connected to the first top portion 241, the first bottom portion 242, the first gate electrodes 213 of the two first semiconductor elements 21, and the second gate electrodes 223 of the two second semiconductor elements 22.

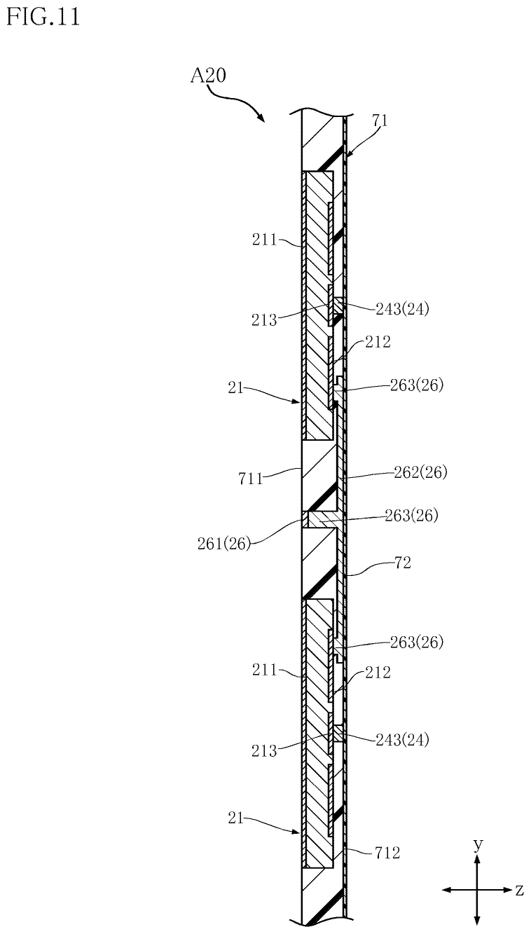

As shown in FIGS. 7 and 9, the first electrodes 211 of the two first semiconductor elements 21 are exposed externally from the top surface 711 of the sealing resin 71. As shown in FIGS. 7 and 10, the third electrodes 221 of the two second semiconductor elements 22 are exposed externally from the top surface 711.

The second signal terminal 25 is exposed externally from the top surface 711 of the sealing resin 71, as shown in FIG. 7. The second signal terminal 25 is located on the same side as the first signal terminal 23 with respect to the two first semiconductor elements 21 in the first direction z. The second signal terminal 25 is spaced apart from the first signal terminal 23 in the second direction y.

The second signal wiring 26 connects the second electrode 212 of each first semiconductor element 21 and the fourth electrode 222 of each second semiconductor element 22 to the second signal terminal 25. At least a portion of the second signal wiring 26 is covered by the sealing resin 71.

As shown in FIGS. 7, 8 and 11, the second signal wiring 26 includes a second top portion 261, a second bottom portion 262 and second via portions 263. The second top portion 261 is exposed externally from the top surface 711 of the sealing resin 71. The second bottom portion 262 is exposed externally from the bottom surface 712 of the sealing resin 71. The second via portions 263 are covered by the sealing resin 71. The second via portions 263 are connected to the second top portion 261, the second bottom portion 262, the second electrodes 212 of the two first semiconductor elements 21, and the fourth electrodes 222 of the two second semiconductor elements 22.

The four bottom terminals 28 individually contact and conduct to the second electrodes 212 of the two first semiconductor elements 21 and the fourth electrodes 222 of the two second semiconductor elements 22, as shown in FIGS. 8 through 10. The four bottom terminals 28 are spaced apart from the first gate electrodes 213 first of the two semiconductor elements 21 and the second gate electrodes 223 of the two second semiconductor elements 22. The four bottom terminals 28 are exposed externally from the bottom surface 712 of the sealing resin 71.

The second signal terminal 25, the second signal wiring 26, and the four bottom terminals 28 may be formed by the LDS method described earlier, as with the first signal terminal 23 and the first signal wiring 24.

The coating layer 72 covers the first bottom portion 242 of the first signal wiring 24 and the second bottom portion 262 of the second signal wiring 26. The coating layer 72 is an insulator. The coating layer 72 is held in contact with the bottom surface 712 of the sealing resin 71. The coating layer 72 is provided by, for example, a solder resist. Next, effects and advantages of the semiconductor device A20 will be explained.

The semiconductor device A20 includes first semiconductor elements 21, second semiconductor elements 22, a first signal terminal 23, a first signal wiring 24, and a sealing resin 71. The first semiconductor element 21 has a first electrode 211, a second electrode 212, and a first gate electrode 213. The second semiconductor element 22 has a third electrode 221, a fourth electrode 222, and a second gate electrode 223. A first linear length L1 is defined as the length connecting the first center C1 of the first gate electrode 213 and the third center C3 of the first signal terminal 23, and a second linear length L2 is defined as the length connecting the second center C2 of the second gate electrode 223 and the third center C3. Further, a first path length R1 is defined as the length from the first center C1 to the third center C3 via the first signal wiring 24, and a second path length R2 is defined as the length from the second center C2 to the third center C3 via the first signal wiring 24. In the semiconductor device A20, the value of the second path length R2/the first path length R1 is closer to 1 than is the value of the second linear length L2/the first linear length L1 (see FIG. 7). Thus, the semiconductor device A20 also makes it possible to achieve uniform application of gate voltage to the multiple semiconductor elements. Further, the semiconductor device A20 may have the same configurations as those of the semiconductor device A10 described above, whereby the semiconductor device A20 can also achieve the same or similar effects and advantages.

The first signal terminal 23 is located opposite to the second electrode 212 with respect to the first semiconductor element 21 in the first direction z. With this configuration, when the second electrode 212 is conductively bonded to a conductive member in mounting the semiconductor device A20, the first signal terminal 23 is configured to be located opposite to the side facing the conductive member in the first direction z. Advantageously, this facilitates conductive bonding of wires or other elements to the first signal terminal 23.

The semiconductor device A20 further includes a second signal terminal 25 and a second signal wiring 26. The second signal wiring 26 conducts the second electrodes 212 of the first semiconductor elements 21 and the fourth electrodes 222 of the second semiconductor elements 22 to the second signal terminal 25. The second signal terminal 25 is located on the same side as the first signal terminal 23 with respect to the first semiconductor elements 21 in the first direction z. With this configuration, when the second electrode 212 is conductively bonded to a conductive member in mounting the semiconductor device A20, the same configurations as those described above with the first signal terminal 23 result. Advantageously, this facilitates conductive bonding of wires or other elements to the second signal terminal 25.

The semiconductor device A20 further includes an insulating coating layer 72. The first bottom portion 242 of the first signal wiring 24 is exposed from the sealing resin 71. The coating layer 72 covers the first bottom portion 242. This configuration prevents a short circuit between the first signal wiring 24 and the second electrode 212 due to solder or the like in conductively bonding the second electrode 212 to a conductive member for mounting the semiconductor device A20.

### Third Embodiment

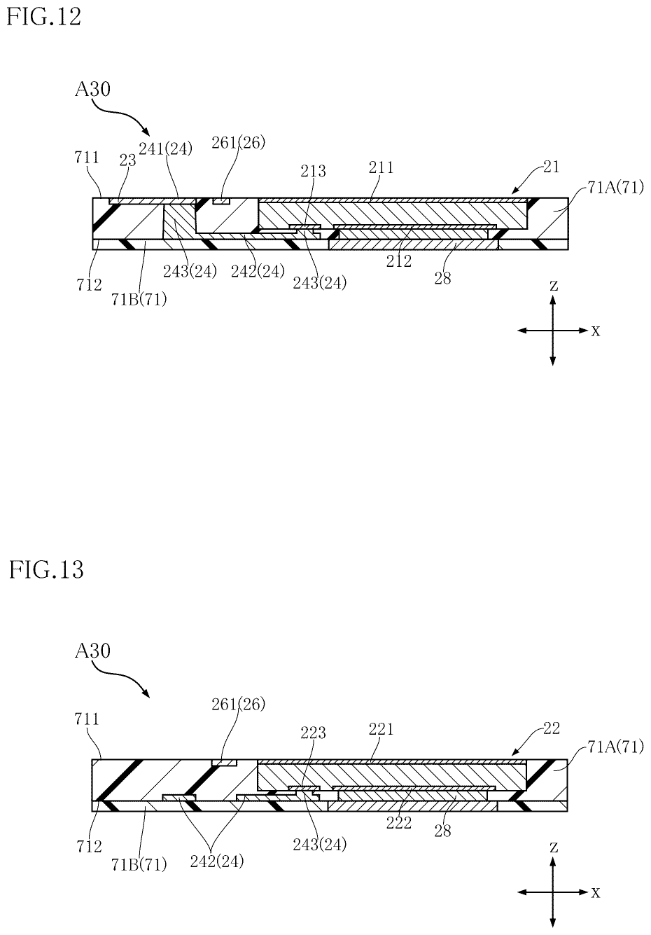

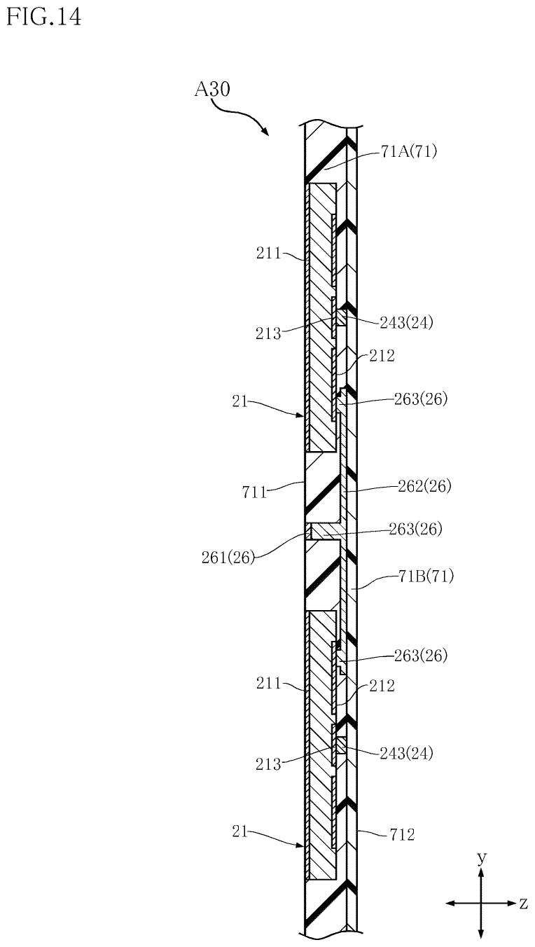

A semiconductor device A30 according to a third embodiment of the present disclosure is described below based on FIGS. 12 through 14. In these figures, the same or similar elements to those of the semiconductor device A10 described above are indicated by the same symbols, and redundant explanations are omitted. The cross-sectional location in FIG. 12 is the same as with the cross-sectional location in FIG. 9 showing the semiconductor device A20. The cross-sectional location in FIG. 13 is the same as with location in FIG. 10 showing the the cross-sectional semiconductor device A20. The cross-sectional location in FIG. 14 is the same as with the cross-sectional location in FIG. 11 showing the semiconductor device A20.

In the semiconductor device A30, the configuration of the sealing resin 71 differs from that of the semiconductor device A20 described above. Unlike the semiconductor device A20, the semiconductor device A30 does not includes a coating layer 72.

As shown in FIGS. 12 through 14, the sealing resin 71 includes a first layer 71A and a second layer 71B. The first layer 71A includes a top surface 711. The second layer 71B is stacked on the first layer 71A on a side facing in the first direction z. The second layer 71B includes a bottom surface 712. The first bottom portion 242 of the first signal wiring 24 and the second bottom portion 262 of the second signal wiring 26 are covered by the second layer 71B.

Next effects and advantages of the semiconductor device A30 are described below.

The semiconductor device A30 includes first semiconductor elements 21, second semiconductor elements 22, a first signal terminal 23, a first signal wiring 24, and a sealing resin 71. The first semiconductor element 21 includes a first electrode 211, a second electrode 212, and a first gate electrode 213. The second semiconductor element 22 includes a third electrode 221, a fourth electrode 222, and a second gate electrode 223. A first linear length L1 is defined as the length connecting the first center C1 of the first gate electrode 213 and the third center C3 of the first signal terminal 23, and a second linear length L2 is defined as the length connecting the second center C2 of the second gate electrode 223 and the third center C3. A first path length R1 is defined as the length from the first center C1 to the third center C3 via the first signal wiring 24 and a second path length R2 is defined as the length from the second center C2 to the third center C3 via the first signal wiring 24. In the semiconductor device A20, the value of the second path length R2/the first path length R1 is closer to 1 than is the value of the second linear length L2/the first linear length L1 (see FIG. 7). Thus, the semiconductor device A30 also makes it possible to achieve uniform application of the gate voltage to the multiple semiconductor elements. Further, the semiconductor device A30 may have the same configurations as those of the semiconductor device A10, so that the semiconductor device A30 also achieves the same or similar effects and advantages.

The first bottom portion 242 of the first signal wiring 24 is covered by the sealing resin 71. This configuration prevents a short circuit between the first signal wiring 24 and the second electrode 212 due to solder or the like when conductively bonding the second electrode 212 to a conductive member in mounting the semiconductor device A30. Further, the above configuration causes the dimension of the sealing resin 71 in the first direction z to be increased, whereby the semiconductor device A30 is more robust against bending around the direction perpendicular to the first direction z.

### Fourth Embodiment

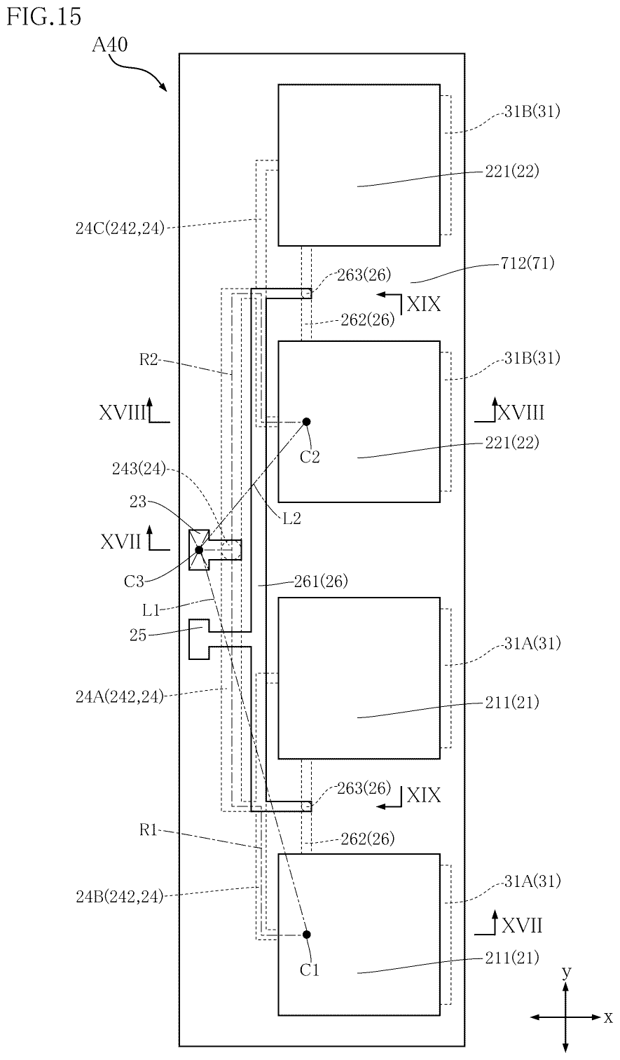

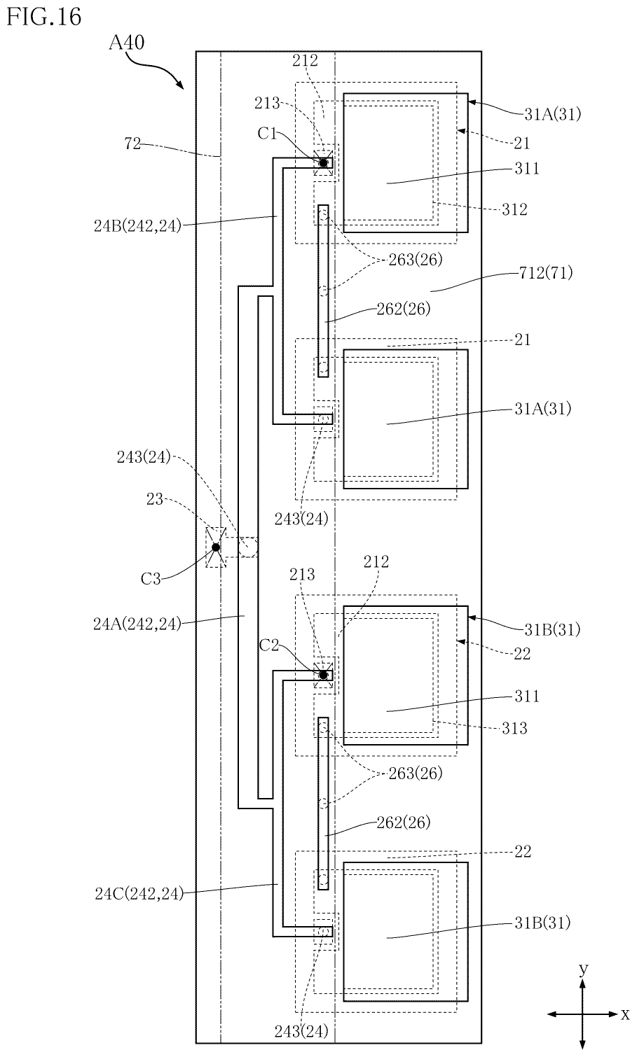

Referring to FIGS. 15 through 19, a semiconductor device A40 of a fourth embodiment of the present disclosure is described. In these figures, the same or similar elements as those in the semiconductor device A10 described above are indicated by the same symbol, and redundant explanations are omitted. In FIG. 16, for convenience of understanding, the coating layer 72 is shown as a transparent component, and the outline of the coating layer 72 is shown by an imaginary line.

The semiconductor device A40 further includes a heat transfer layer 31 and a junction layer 32 with respect to semiconductor device A20. Unlike the semiconductor device A20, the semiconductor device A40 does not include bottom terminals 28.

In the semiconductor device A40, the heat transfer layer 31 includes two first heat transfer layers 31A and two second heat transfer layers 31B, as shown in FIG. 15. The two first heat transfer layers 31A are conductively bonded to the second electrodes 212 of the two first semiconductor elements 21, respectively. The two first heat transfer layers 31A are spaced apart from the first gate electrodes 213 of the two first semiconductor elements 21. The dimension in the first direction z of each first heat transfer layer 31A is larger than the dimension in the first direction z of each first semiconductor element 21. The two second heat transfer layers 31B are conductively bonded to the fourth electrodes 222 of the two second semiconductor elements 22, respectively. The two second heat transfer layers 31B are spaced apart from the second gate electrodes 223 of the two second semiconductor elements 22. The dimension in the first direction z of each second heat transfer layer 31B is larger than the dimension in the first direction z of each second semiconductor element 22. The composition of the heat transfer layer 31 includes copper (Cu).

As shown in FIGS. 16, 17 and 19, the two first heat transfer layers 31A have a first surface 311 and a second surface 312. The first surface 311 and the second surface 312 face opposite from each other in the first direction z. The first surface 311 is exposed externally from the bottom surface 712 of the sealing resin 71. The second electrodes 212 of the two first semiconductor elements 21 are conductively bonded to the second surfaces 312 of the two first heat transfer layers 31A, respectively. As viewed in the first direction z, the entire second surface 312 overlaps with the first surface 311.

As shown in FIGS. 16, 18 and 19, the two second heat transfer layers 31B have a first surface 311 and a third surface 313. The first surface 311 and the third surface 313 face opposite from each other in the first direction z. The first surface 311 is exposed externally from the bottom surface 712 of the sealing resin 71. The fourth electrodes 222 of the two second semiconductor elements are 22 conductively bonded to the third surfaces 313 of the two second heat transfer layers 31B, respectively. As viewed in the first direction z, the entire third surface 313 overlaps with the first surface 311.

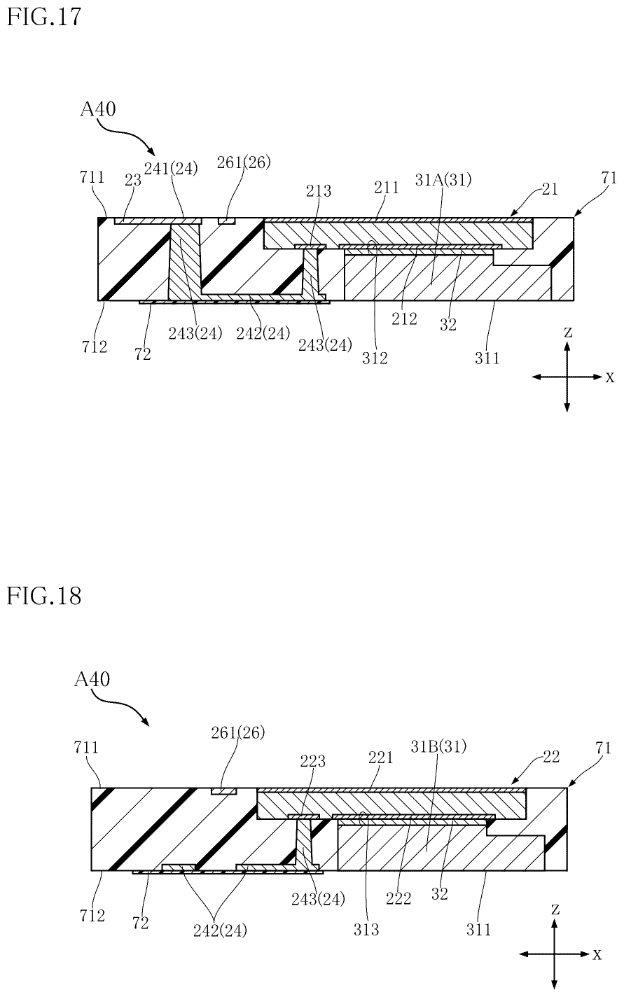

The junction layer 32 conductively bonds the second electrodes 212 of the two first semiconductor elements 21 and the fourth electrodes 222 of the two second semiconductor elements 22 to the heat transfer layer 31, as shown in FIGS. 17 through 19. The composition of the junction layer 32 includes aluminum (Al). Alternatively, the junction layer 32 may include a metal layer whose composition may contain aluminum, and two silver layers sandwiching the metal layer in the first direction z. In this case, the thickness of each silver layer may be smaller than that of the metal layer. The second electrode 212 is conductively bonded to the second surface 312 of either of the two first heat transfer layers 31A by solid phase diffusion via the junction layer 32. The fourth electrode 222 is conductively bonded to the third surface 313 of either of the two second heat transfer layers 31B by solid phase diffusion via the junction layer 32.

### Variation of Fourth Embodiment

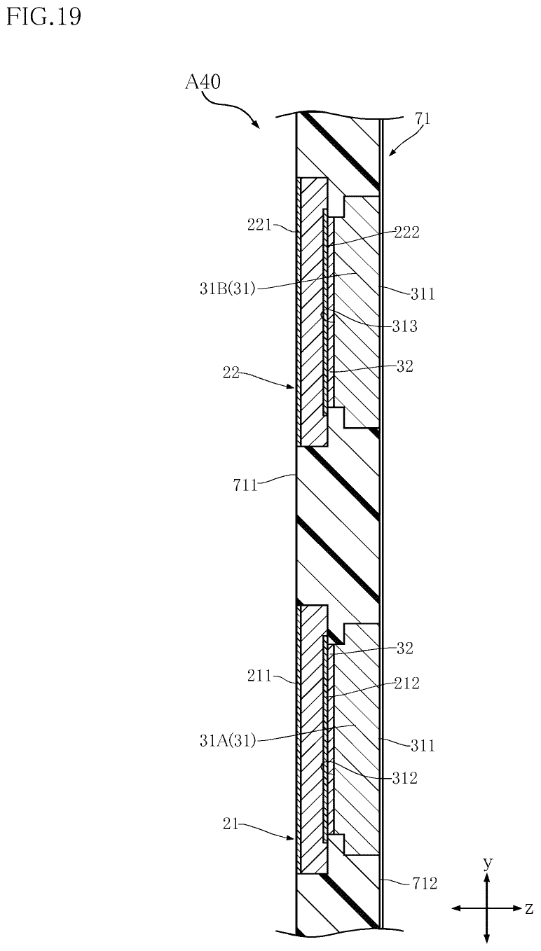

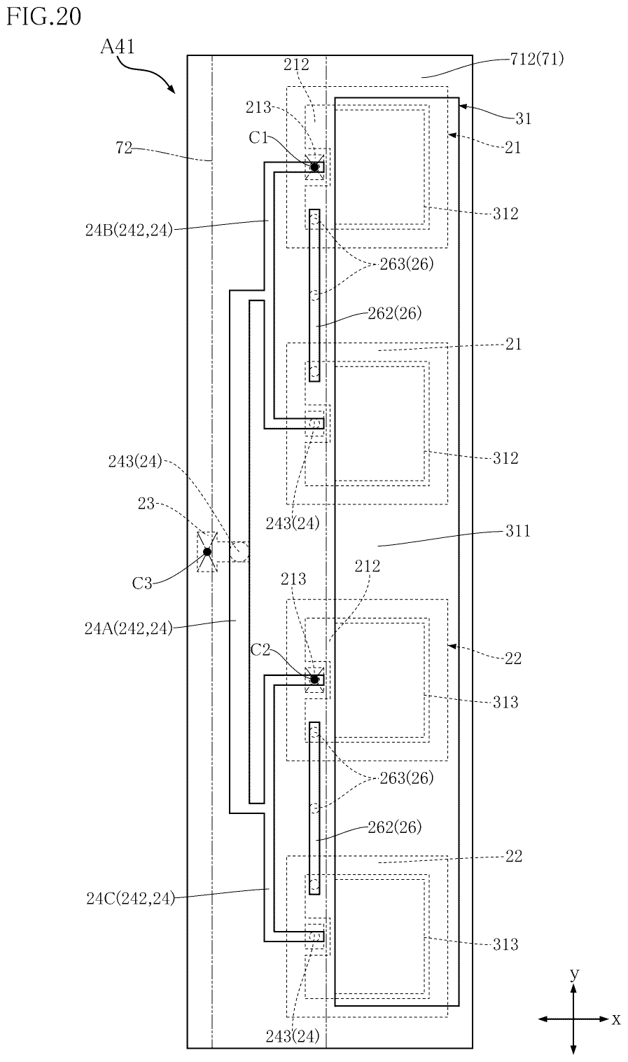

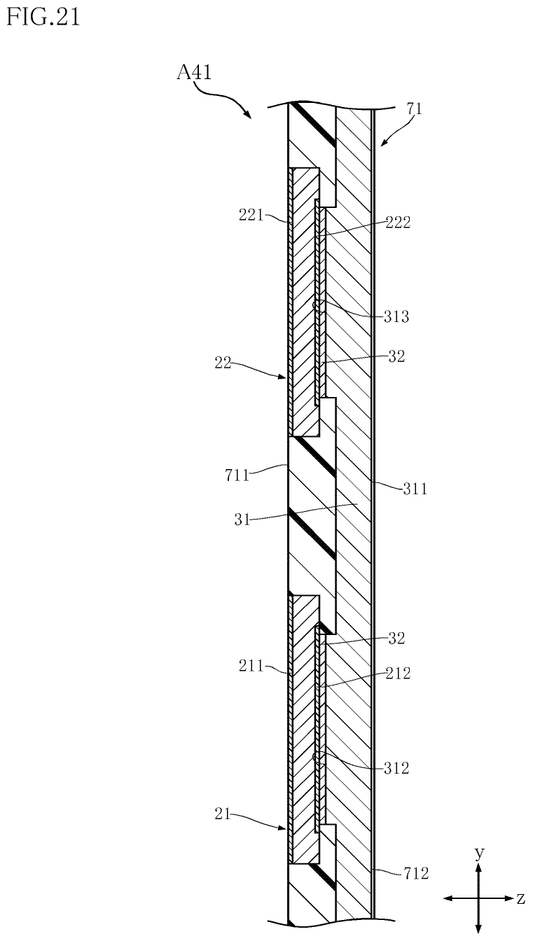

Next, referring to FIGS. 20 and 21, a semiconductor device A41, which is a variant of the semiconductor device A40, is described. The cross-sectional location of FIG. 21 is the same as that of FIG. 19 showing the semiconductor device A40.

As shown in FIGS. 20 and 21, in the semiconductor device A41, the heat transfer layer 31 has a single-layer configuration. The heat transfer layer 31 includes a first surface 311, two second surfaces 312, and two third surfaces 313. The first surface 311 extends elongate in the second direction y. The second electrodes 212 of the two first semiconductor elements 21 are conductively bonded to the two second surfaces 312, respectively. The fourth electrodes 222 of the two second semiconductor elements 22 are conductively bonded to the two third surfaces 313, respectively.

Next, effects and advantages of the semiconductor device A40 is described below.

The semiconductor device A40 includes first semiconductor elements 21, second semiconductor elements 22, a first signal terminal 23, a first signal wiring 24, and a sealing resin 71. The first semiconductor element 21 has a first electrode 211, a second electrode 212, and a first gate electrode 213. The second semiconductor element 22 has a third electrode 221, a fourth electrode 222, and a second gate electrode 223. A first linear length L1 is defined as the length connecting the first center C1 of the first gate electrode 213 and the third center C3 of the first signal terminal 23, and a second linear length L2 is defined as the length connecting the second center C2 of the second gate electrode 223 and the third center C3. A first path length R1 is defined as the length from the first center C1 to the third center C3 via the first signal wiring 24, and a second path length R2 is defined as the length from the second center C2 to the third center C3 via the first signal wiring 24. In the semiconductor device A40, the value of the second path length R2/the first path length R1 is closer to 1 than is the value of the second linear length L2/the first linear length L1 (see FIG. 16). Thus, in the semiconductor device A40, it is possible to achieve uniform application of gate voltage to each of the semiconductor elements. Further, the semiconductor device A40 may have the same configuration as that of the semiconductor device A10, whereby the semiconductor device A40 can also achieve the same effects and advantages.

The semiconductor device A40 further includes a heat transfer layer 31 located away from the first gate electrode 213. The heat transfer layer 31 has a first surface 311 exposed externally from the sealing resin 71 and a second surface 312 to which the second electrode 212 is conductively bonded. As viewed in the first direction z, the entire second surface 312 overlaps with the first surface 311. It is now supposed that the heat transfer layer 31 is provided with a virtual plane which extends from the periphery of the second surface 312 toward the first surface 311 with an inclination of 45° relative to the first direction z. Then, the heat conducted to the heat transfer layer 31 would diffuse uniformly in the area surrounded by the virtual plane. Accordingly, with the present configuration, heat conducted from the second surface 312 to the heat transfer layer 31 is more likely to diffuse uniformly in the first direction z and in a direction orthogonal to the first direction z. Thus, heat conducted from the second electrode 212 of the first semiconductor element 21 to the heat transfer layer 31 is more quickly released to the outside. In this manner, the heat dissipation of the semiconductor device A40 can be improved while preventing a short circuit from occurring with the first gate electrode 213.

### Semiconductor Module B10:

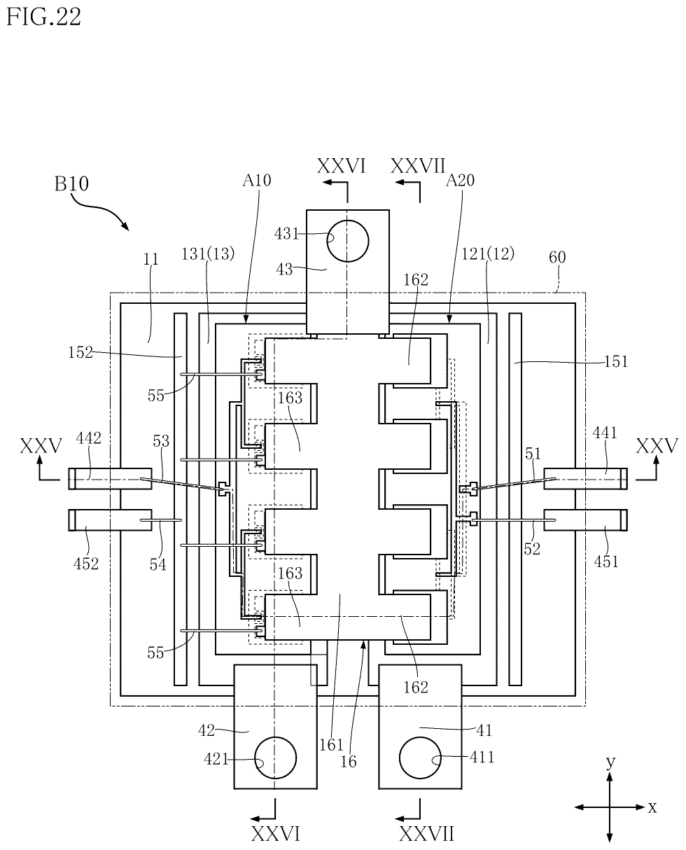

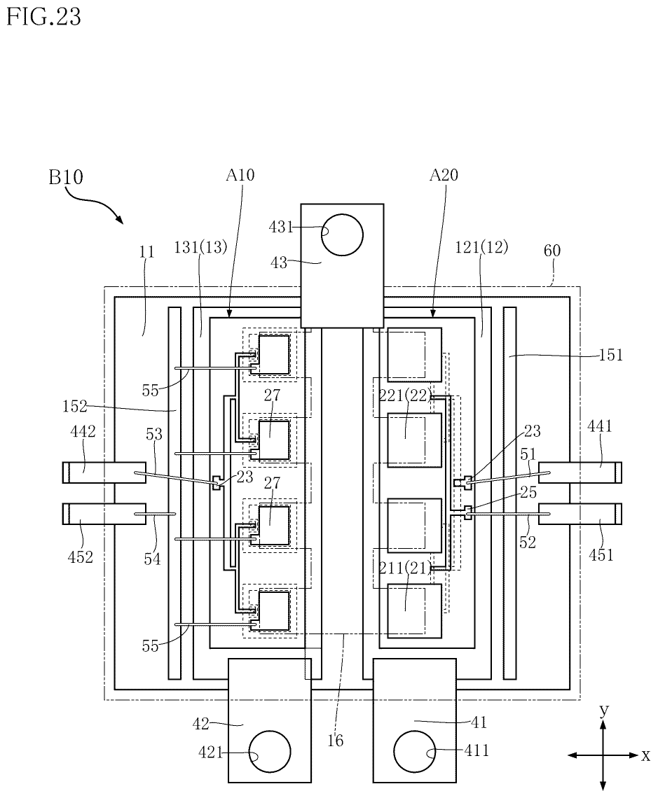

Next, referring to FIGS. 22 to 29, a semiconductor module B10 according an embodiment of the present disclosure is described. The semiconductor module B10 includes a semiconductor device A10, a semiconductor device A20, a substrate 11, a first conductive member 12, a second conductive member 13, a conducting member 16, a first input terminal 41, a second input terminal 42, an output terminal 43 and a mold resin 60. Further, the semiconductor module B10 includes a first detection wiring layer 151, a second detection wiring layer 152, a heat dissipation layer 17, a first gate terminal 441, a second gate terminal 442, a first detection terminal 451 and a second detection terminal 452. FIG. 22 shows the mold resin 60 transparently for convenience of understanding. Like FIG. 22, FIG. 23 shows the conducting member 16 transparently for convenience of understanding. In FIGS. 22 and 23, the outline of the mold resin 60 is shown as an imaginary line. In FIG. 23, the outline of the conducting member 16 is shown as an imaginary line. In FIG. 22, the XXV-XXV and XXVI-XXVI lines are shown as dotted lines.

The semiconductor module B10 converts the DC power supply voltage applied to the first and second input terminals 41 and 42 into AC power by the semiconductor device A10 and the semiconductor device A20. The converted AC power is input to a motor or other power supply target via the output terminal 43. The semiconductor module B10 forms part of a power conversion circuit such as an inverter.

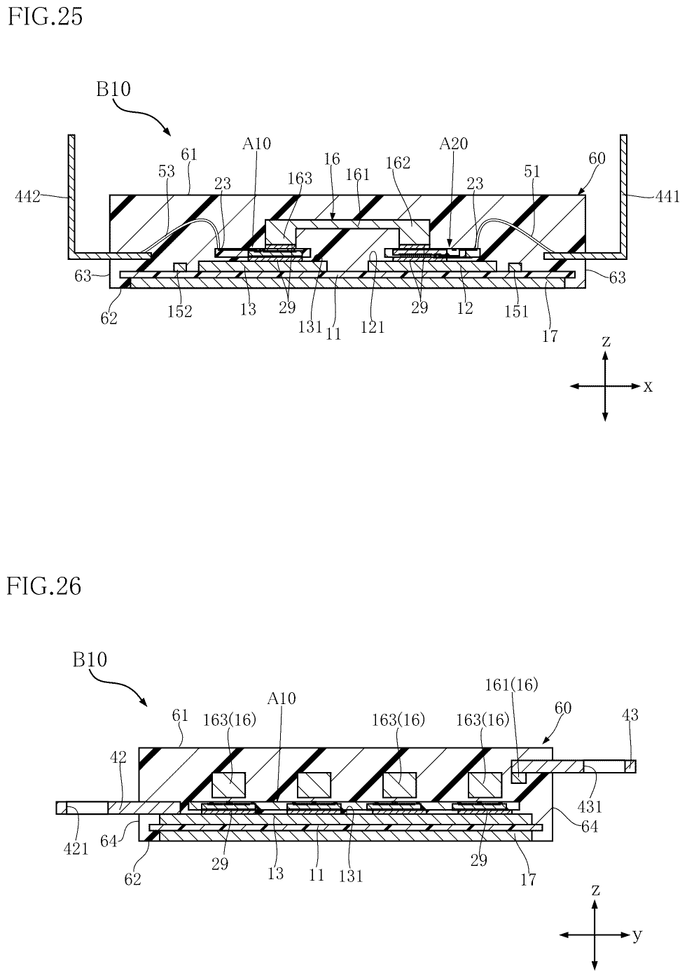

The substrate 11 supports the first conductive member 12, the second conductive member 13, the first detection wiring layer 151, the second detection wiring layer 152, and the heat radiation layer 17, as shown in FIG. 25. The substrate 11 is electrically insulating. The substrate 11 is made of a material with a higher thermal conductivity. The substrate 11 is made of ceramics, including aluminum nitride (AlN), for example. The periphery of the substrate 11 is sandwiched between the mold resin 60 in the first direction z. The thickness of the substrate 11 is smaller than the thickness of each of the first conductive member 12, the second conductive member 13, and the heat dissipation layer 17.

The first conductive member 12 carries the semiconductor device A20, as shown in FIGS. 23, 25, and 27. The first conductive member 12 can mount any of the previously mentioned semiconductor devices A30, A40 and A41 besides the semiconductor device A20. The first conductive member 12 is rectangular in shape and elongated in the second direction y. As viewed in the first direction z, the first conductive member 12 is surrounded by the periphery of the substrate 11. The composition of the first conductive member 12 includes copper. The first conductive member 12 has a first obverse surface 121 facing in the first direction Z. The semiconductor device A20 faces the first obverse surface 121. The second conductive member 13 carries the semiconductor device A10, as shown in FIGS. 23, 25, and 26. The second conductive member 13 is located away from the first conductive member 12 in the third direction x. The second conductive member 13 is rectangular and elongated in the second direction y. As viewed in the first direction z, the second conductive member 13 is surrounded by the periphery of the substrate 11. The composition of the second conductive member 13 includes copper. The second conductive member 13 has a second obverse surface 131 facing the same side as the first obverse surface 121 of the first conductive member 12 in the first direction z. The semiconductor device A10 faces the second obverse surface 131.

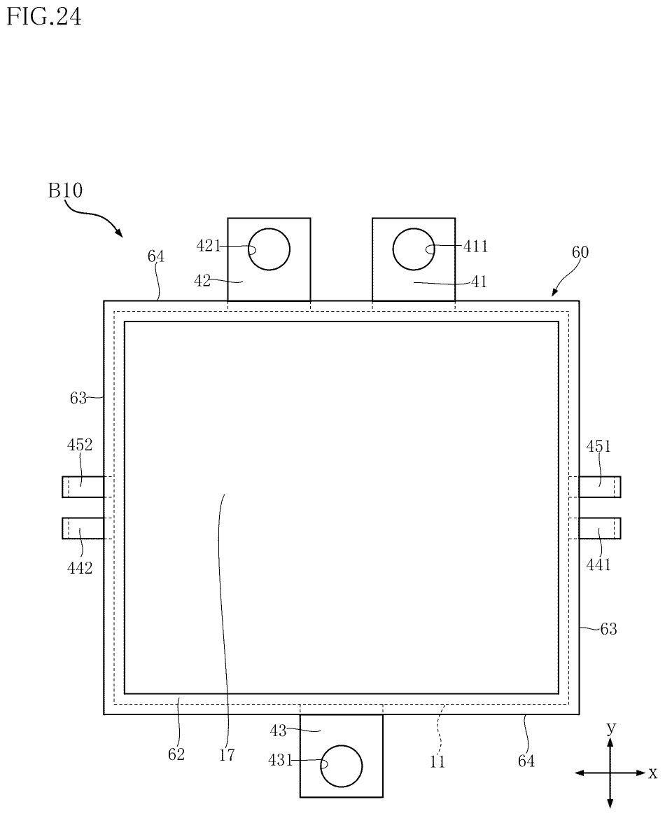

The heat dissipation layer 17 is located opposite to the first and second conductive members 12 and 13 with respect to the substrate 11 in the first direction z, as shown in FIGS. 25 to 27. The heat dissipation layer 17 is supported by the substrate 11. The heat dissipation layer 17 is exposed from the mold resin 60. The volume of the heat dissipation layer 17 is greater than the sum of the volumes of the first and second conductive members 12 and 13. As shown in FIG. 24, the heat dissipation layer 17 is surrounded by the periphery of the substrate 11, as viewed in the first direction z. The composition of the heat dissipation layer 17 includes copper. When the semiconductor module B10 is used, a heat sink (not shown) is bonded to the heat dissipation layer 17.

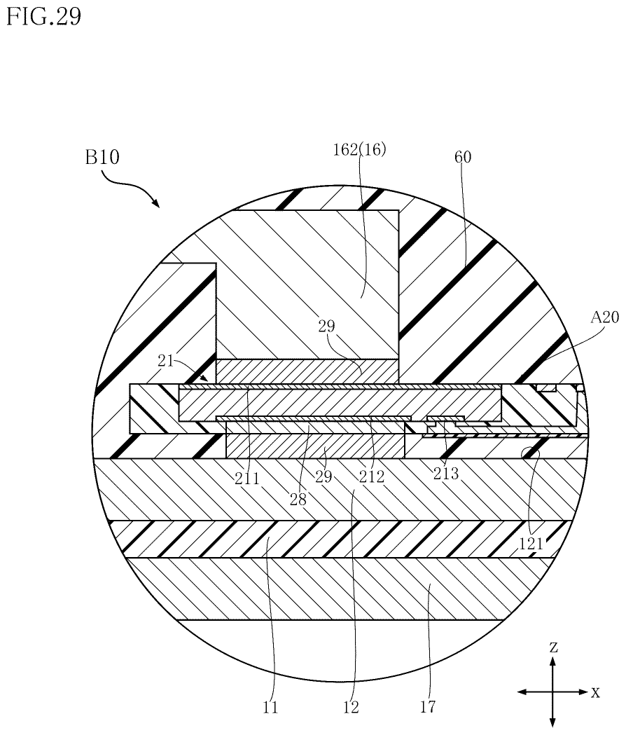

As shown in FIG. 28, the first electrodes 211 of the two first semiconductor elements 21 of the semiconductor device A10 and the third electrodes 221 of the two second semiconductor elements 22 of the semiconductor device A10 (the third electrodes 221 are not shown) are conductively bonded to the second obverse surface 131 of the second conductive member 13 via a conductive bonding layer 29. Thus, the first and third electrodes 211 and 221 of the semiconductor device A10 are located between the second conductive member 13 and the first signal terminal 23 in the first direction z. The first and third electrodes 211 and 221 of the semiconductor device A10 are electrically connected to the second conductive member 13. The conductive bonding layer 29 is, for example, made of solder. Alternatively, the conductive bonding layer 29 may be made of a sintered metal containing silver (Ag) or other metals.

As shown in FIG. 29, the four bottom terminals 28 of the semiconductor device A20 are conductively bonded to the first obverse surface 121 of the first conductive member 12 via a conductive bonding layer 29. Thus, the second electrode 212 and fourth electrode 222 of the semiconductor device A20 are located between the first conductive member 12 and the first signal terminal 23 in the first direction z. The second and fourth electrodes 212 and 222 of the semiconductor device A20 are electrically connected to the first conductive member 12.

In the semiconductor module B10, the semiconductor device A10 constitutes part of the upper arm circuit and the semiconductor device A20 constitutes part of the lower arm circuit.

The first gate terminal 441 is located opposite to the second conductive member r 13 with respect to the first conductive member 12 in the third direction x, as shown in FIGS. 22 and 23. The first gate terminal 441 is a metal lead made of a material including copper or a copper alloy. As shown in FIG. 25, a part of the first gate terminal 441 is covered by the mold resin 60. As viewed in the second direction y, the first gate terminal 441 is L-shaped. The first gate terminal 441 includes a portion raised in the first direction z. This raised portion is exposed from the mold resin 60. A gate voltage is applied to the first gate terminal 441 to drive the two first semiconductor elements 21 of the semiconductor device A20 and the two second semiconductor elements 22 of the semiconductor device A20.

As shown in FIG. 23, the semiconductor module B10 further includes a first wire 51. The first wire 51 is conductively bonded to the first signal terminal 23 of the semiconductor device A20 and the first gate terminal 441. Thus, the first signal terminal 23 of the semiconductor device A20 is electrically connected to the first gate terminal 441. The composition of the first wire 51 includes gold (Au). Alternatively, the composition of the first wire 51 may include copper or aluminum, for example.

The second gate terminal 442 is located opposite to the first conductive member 12 with respect to the second conductive member 13 in the third direction x, as shown in FIGS. 22 and 23. The second gate terminal 442 is a metal lead made of a material including copper or a copper alloy. As shown in FIG. 25, a part of the second gate terminal 442 is covered by the mold resin 60. As viewed in the second direction y, the second gate terminal 442 is L-shaped. The second gate terminal 442 includes a portion raised in the first direction z. This raised portion is exposed from the mold resin 60. A gate voltage is applied to the second gate terminal 442 to drive the two first semiconductor elements 21 of the semiconductor device A10 and the two second semiconductor elements 22 of the semiconductor device A10.

As shown in FIG. 23, the semiconductor module B10 further includes a third wire 53. The third wire 53 is conductively bonded to the first signal terminal 23 of the semiconductor device A10 and the second gate terminal 442. Thus, the first signal terminal 23 of semiconductor device A10 is connected to the second gate terminal 442. The composition of the third wire 53 includes gold. Alternatively, the composition of the third wire 53 may include copper or aluminum, for example.

The first detection wiring layer 151 is located between the first conductive member 12 and the first gate terminal 441 in the third direction x, as shown in FIGS. 22, 23 and 25. The first detection wiring layer 151 extends elongated in the second direction y. The composition of the first detection wiring layer 151 includes copper.

The first detection terminal 451 is located opposite to the first conductive member 12 with respect to the first detection wiring layer 151 in the third direction x, as shown in FIGS. 22 and 23. The first detection terminal 451 is located next to the first gate terminal 441 in the second direction y. The first detection terminal 451 is a metal lead made of a material including copper or a copper alloy. A part of the first detection terminal 451 is covered by the mold resin 60. As viewed in the second direction y, the first detection terminal 451 is L-shaped. The first detection terminal 451 includes a portion raised in the first direction z. This raised portion is exposed from the mold resin 60. A voltage of equal potential to the voltage applied to the second electrodes 212 of the two first semiconductor elements 21 of the semiconductor device A20 and the fourth electrodes 222 of the two second semiconductor elements 22 of the semiconductor device A20 is applied to the first detection terminal 451.

As shown in FIG. 23, the semiconductor module B10 further includes a second wire 52. The second wire 52 is conductively bonded to the second signal terminal 25 of the semiconductor device A20 and the first detection terminal 451. Thus, The second signal terminal 25 of the semiconductor device A20 is electrically connected to the first detection terminal 451. The composition of the second wire 52 includes gold. Alternatively, the composition of the second wire 52 may include copper or aluminum, for example.

The second detection wiring layer 152 is located between the second conductive member 13 and the second gate terminal 442 in the third direction x, as shown in FIGS. 22, 23 and 25. The second detection wiring layer 152 extends elongated in the second direction y. The composition of the second detection wiring layer 152 includes copper.

The second detection terminal 452 is located opposite to the second conductive member 13 with respect to the second detection wiring layer 152 in the third direction x, as shown in FIGS. 22 and 23. The second detection terminal 452 is located next to the second gate terminal 442 in the second direction y. The second detection terminal 452 is a metal lead made of a material including copper or a copper alloy. A part of the second detection terminal 452 is covered by the mold resin 60. As viewed in the second direction y, the second detection terminal 452 is L-shaped. The second detection terminal 452 includes a portion raised in the first direction z. This raised portion is exposed from the mold resin 60. A voltage of equal potential to the voltage applied to the second electrodes 212 of the two first semiconductor elements 21 of the semiconductor device A10 and the fourth electrodes 222 of the two second semiconductor elements 22 of the semiconductor device A10 is applied to the second detection terminal 452.

As shown in FIG. 23, the semiconductor module B10 further includes a fourth wire 54. The fourth wire 54 is conductively bonded to the second detection terminal 452 and the second detection wiring layer 152. Thus, The second detection terminal 452 is electrically connected to the second detection wiring layer 152. The composition of the fourth wire 54 includes gold. Alternatively, the composition of the fourth wire 54 may include copper or aluminum, for example.

As shown in FIG. 23, the semiconductor module B10 further includes a plurality of fifth wires 55. Each fifth wire 55 is conductively bonded to one of the top terminals 27 of the semiconductor device A10 and the first detection wiring layer 151. Thus, the second electrodes 212 of the two first semiconductor elements 21 of the semiconductor device A10 and the fourth electrodes 222 of the two second semiconductor elements 22 of the semiconductor device A10 are electrically connected to the second detection terminal 452 via the first detection wiring layer 151. The composition of the fifth wires 55 includes gold. Alternatively, the composition of each fifth wire 55 may include copper or aluminum, for example.

The conducting member 16 is spaced apart from the substrate 11 toward the side in which the first obverse surface 121 of the first conductive member 12 faces in the first direction z, as shown in FIGS. 25 through 27. The conducting member 16 connects the second electrodes 212 of the two first semiconductor elements 21 of the semiconductor device A10, the fourth electrodes 222 of the two second semiconductor elements 22 of the semiconductor device A10, the first electrodes 211 of the two first semiconductor elements 21 of the semiconductor device A20, and the the third electrodes 221 of the two second semiconductor elements 22 of the second semiconductor device A20 to each other. The composition of the conducting member 16 includes copper. The conducting member 16 is a flat plate.

As shown in FIGS. 22 and 25 through 27, the conduction member 16 includes a main portion 161, a plurality of first connecting portions 162, and a plurality of second connecting portions 163. The main portion 161 extends elongated in the second direction y. As viewed in the first direction z, the main portion 161 overlaps with the first and second conductive members 12, 13 and with the area of the substrate 11 located between the first and the second conductive members 12 and 13.

As shown in FIGS. 22 and 25, the first connecting portions 162 are connected to one side of the main portion 161 in the third direction x. The first connecting portions 162 each extend in the third direction x and are mutually arranged in the second direction y. As shown in FIG. 29, the first connecting portions 162 are conductively bonded to the first electrodes 211 of the two first semiconductor elements 21 and the third electrodes 221 of the two second semiconductor elements 22 of the semiconductor device A20 via the conductive bonding layer 29.

As shown in FIGS. 22 and 25, the second connecting portions 163 are located opposite to the first connecting portions 162 with respect to the main portion 161 in the third direction x and are connected to the main portion 161. The plurality of second connections 163 each extend in the third direction x and are mutually arranged in the second direction y. As viewed in the first direction z, the shape and dimensions of each second connecting portion 163 is equal to the shape and dimensions of each first connecting portion 162. As shown in FIG. 28, the second connecting portions 163 are conductively bonded to the second electrodes 212 of the two first semiconductor elements 21 and the fourth electrodes 222 of the two second semiconductor elements 22 of the semiconductor device A10 via the relevant conductive bonding layers 29, respectively.

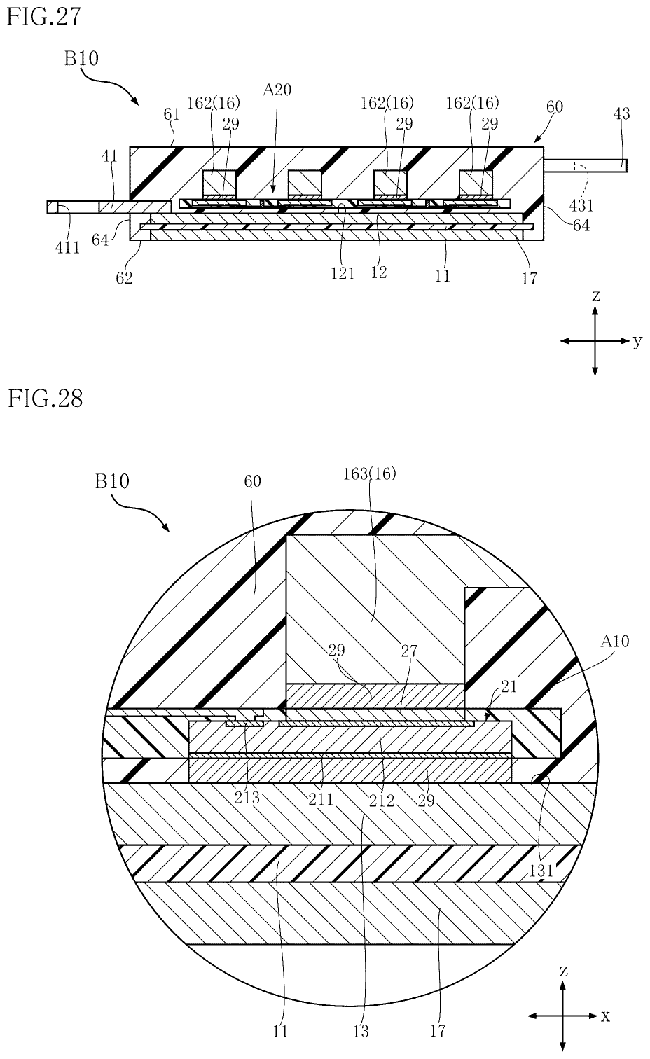

The first input terminal 41 is located on one side of the second direction y with respect to the substrate 11, as shown in FIGS. 22 and 23. As shown in FIG. 27, the first input terminal 41 is conductively bonded to the first conductive member 12. Thus, the first input terminal 41 is electrically connected to the second electrodes 212 of the two first semiconductor elements 21 of the semiconductor device A20 and the fourth electrodes 222 of the two second semiconductor elements 22 of the semiconductor device A20 via the first conductive member 12. The first input terminal 41 is a metal plate made of a material including copper or a copper alloy. A part of the first input terminal 41 is covered by the mold resin 60. The first input terminal 41 is formed with a first mounting hole 411 that penetrates in the first direction z. The first mounting hole 411 is located away from the mold resin 60. The first input terminal 41 is an N terminal (negative polarity) to which DC power supply voltage to be converted is applied.

The second input terminal 42 is located on the same side as the first input terminal 41 with respect to the substrate 11 in the second direction y, as shown in FIGS. 22 and 23. The second input terminal 42 is spaced apart from the first input terminal 41 in the third direction x. As shown in FIG. 26, the second input terminal 42 is conductively bonded to the second conductive member 13. Thus, the second input terminal 42 is electrically connected to the first electrodes 211 of the two first semiconductor elements 21 of the semiconductor device A10 and the third electrodes 221 of the two first semiconductor elements 21 of the semiconductor device A10 via the second conductive member 13. The second input terminal 42 is a metal plate made of a material including copper or a copper alloy. A part of the second input terminal 42 is covered by the mold resin 60. The second input terminal 42 is formed with a second mounting hole 421 that penetrates in the first direction z. The second mounting hole 421 is located away from the mold resin 60. The second input terminal 42 is a P terminal (positive polarity) to which DC power supply voltage to be converted is applied.

The output terminal 43 is located opposite to the first input terminal 41 and the second input terminal 42 with respect to the substrate 11 in the second direction y, as shown in FIG. 22. As shown in FIG. 26, the output terminal 43 is spaced apart from the substrate 11 toward the side in which the first obverse surface 121 of the first conductive member 12 faces in the first direction z. The output terminal 43 is conductively bonded to the main portion 161 of the conducting member 16. Thus, the output terminal 43 is electrically connected to the second electrodes 212 of the two first semiconductor elements 21 of the semiconductor device A10, the fourth electrodes 222 of the two second semiconductor elements 22 of the semiconductor device A10, the first electrodes 211 of the two first semiconductor elements 21 of the semiconductor device A20, and the third electrodes 221 of the two second semiconductor elements 22 of the semiconductor device A20 via the connecting member 16. The output terminal 43 is a metal plate made of a material containing copper or a copper alloy. A part of the output terminal 43 is covered by the mold resin 60. The output terminal 43 is formed with a third mounting hole 431 that penetrates in the first direction z. The third mounting hole 431 is spaced apart from the mold resin 60. The AC power converted by the semiconductor devices A10 and A20 is output from the output terminal 43.

The mold resin 60 covers the first conductive member 12, the second conductive member 13, the first detection wiring layer 151, the second detection wiring layer 152, and the conducting member 16, as shown in FIGS. 25 through 27. Further, the mold resin 60 covers a portion of each of the substrate 11, the first input terminal 41, the second input terminal 42, the output terminal 43, the first gate terminal 441, the second gate terminal 442, the first detection terminal 451 and the second detection terminal 452. The mold resin 60 is electrically insulating. The mold resin 60 is made of a material containing a black epoxy resin, for example. A portion of the mold resin 60 is sandwiched between the substrate 11 and the main portion 161 of the conducting member 16 in the first direction z.

As shown in FIGS. 24 through 27, the mold resin 60 includes a top surface 61, a bottom surface 62, two first side surfaces 63, and two second side surfaces 64. The top surface 61 faces the same side as the first obverse surface 121 of the first conductive member 12 in the first direction z. The bottom surface 62 faces opposite away from the top surface 61 in the first direction z. The heat dissipation layer 17 is exposed from the bottom surface 62.

As shown in FIGS. 24 and 25, the two first side surfaces 63 are spaced apart from each other in the third direction x and are connected to the top surface 61 and the bottom surface 62. The first gate terminal 441 and the first detection terminal 451 are exposed from one of the two first side surfaces 63, while the second gate terminal 442 and the second detection terminal 452 are exposed from the other first side surface 63.

As shown in FIGS. 24, 26 and 27, the two second side surfaces 64 are spaced apart from each other in the second direction y and are connected to the top surface 61 and the bottom surface 62. The first input terminal 41 and the second input terminal 42 are exposed from one of the two second side surfaces 64, while the output terminal 43 is exposed from the other second side surface 64.

Next, effects and advantages of the semiconductor module B10 are described.

The semiconductor module B10 is equipped with the second conductive member 13 and the semiconductor device A10. The semiconductor device A10 is conductively bonded to the second conductive member 13. The first electrode 211 of the first semiconductor element 21 and the third electrode 221 of the second semiconductor element 22 are located between the second conductive member 13 and the first signal terminal 23 in the first direction z. This configuration makes it possible to achieve uniform application of the gate voltage applied to the semiconductor elements of the semiconductor device A10. Further, it is possible to conductively bond the semiconductor elements of the semiconductor device A10 to the second conductive member 13 efficiently.

The semiconductor module B10 is equipped with the first conductive member 12 and the semiconductor device A20. The semiconductor device A20 is conductively bonded to the first conductive member 12. The second electrode 212 of the first semiconductor element 21 and the fourth electrode 222 of the second semiconductor element 22 are located between the first conductive member 12 and the first signal terminal 23 in the first direction z. This configuration makes it possible to achieve uniform application of the gate voltage applied to the semiconductor elements of the semiconductor device A20. Further, it is possible to conductively bond a plurality of semiconductor devices of the semiconductor device A20 to the first conductive member 12 efficiently. Further, it is possible to shorten the conductive paths between the semiconductor elements of the semiconductor device A10 and the semiconductor elements of the semiconductor device A20.

The semiconductor module B10 is further provided with a conducting member 16 located on the opposite side to the first and the second conductive members 12, 13 with respect to the semiconductor devices A10 and A20 in the first direction z. The conducting member 16 electrically connects the second and the fourth electrodes 212, 222 of the semiconductor device A10 and the first and the third electrodes 211 and 221 of the semiconductor device A20 to each other. As viewed in the first direction z, the conducting member 16 overlaps with the region of the substrate 11 located between the first conductive member 12 and the second conductive member 13. In the semiconductor module B10, a parasitic capacitance is formed with the conducting member 16 and the heat dissipation layer 17 as electrode plates and the substrate 11 and the mold resin 60 as dielectric. With the present configuration, it is possible to ensure an appropriately long distance between the conducting member 16 and the heat dissipation layer 17 in the first direction z, and thus the parasitic capacitance can be made smaller. Further, leakage current of the semiconductor module B10 due to parasitic capacitance can be suppressed, whereby noise generated in the semiconductor module B10 can be reduced.

The conducting member 16 includes a main portion 161 extending in the second direction y, a plurality of first connecting portions 162 located on one side of the main portion 161 in the third direction x, and a plurality of second connecting portions 163 located on the other side of the main portion 161 in the third direction x. As viewed in the first direction z, the shape and dimensions of each second connecting portion 163 is equal to the shape and dimensions of each first connecting portion 162. With this configuration, it is possible to reduce the difference between parasitic inductance relating to the path from the second and fourth electrodes 212, 222 of the semiconductor device A10 to the main portion 161 and parasitic inductance relating to the path from the first and third electrodes 211, 221 of the semiconductor device A20 to the main portion 161. Thus, it is possible to balance the power loss from the semiconductor device A10 to the output terminal 43 and the power loss from the output terminal 43 to the semiconductor device A20.

The thickness of the substrate 11 is smaller than the thickness of each of the first and second conductive members 12 and 13. In other words, the thickness of each of the first and second conductive members 12 and 13 is greater than the thickness of the substrate 11. This configuration improves the heat diffusion efficiency in each of the first and second conductive members 12 and 13 in a direction orthogonal to the first direction z. Accordingly, the heat dissipation of the semiconductor module B10 can be improved.

The present disclosure is not limited to the embodiments described above. The specific configuration of each component disclosed herein can be modified in various ways.

The present disclosure includes embodiments described in the following clauses.

### Clause 1.

A semiconductor device comprising:
a first semiconductor element including a first electrode, a second electrode and a first gate electrode both located on an opposite side to the first electrode in a first direction;
a second semiconductor element including a third electrode located on a same side as the first electrode with respect to the first semiconductor element in the first direction, a fourth electrode and a second gate electrode located on an opposite side to the third electrode in the first direction, the second semiconductor element being spaced apart from the first semiconductor element in a second direction perpendicular to the first direction;
a sealing resin covering at least a part of each of the first semiconductor element and the second semiconductor element;
a first signal terminal exposed externally from the sealing resin; and
a first signal wiring electrically connecting the first and the second gate electrodes to the first signal terminal,
wherein as viewed in the first direction, the first gate electrode has a first center,
as viewed in the first direction, the second gate electrode has a second center,
as viewed in the first direction, the first signal terminal has a third center,
a first straight line connecting the first center and the third center has a length of L1,
a second straight line connecting the second center and the third center has a length of L2,
a first path from the first center to the third center via the first signal wiring has a length of R1,
a second path from the second center to the third center via the first signal wiring has a length of R2,
R2/R1 is closer to 1 than is L2/L1.

### Clause 2.

The semiconductor device according to clause 1, wherein the length of the second path is equal to the length of the first path.

### Clause 3.

The semiconductor device according to clause 1, wherein the length of the second path is not smaller than 85% and not greater than 115% of the length of the first path.

### Clause 4.

The semiconductor device according to any one of clauses 1 to 3, wherein the first signal wiring includes a first wiring extending in the second direction and electrically connected to the first signal terminal, and a second wiring electrically connected to the first wiring and the first gate electrode,
a cross-sectional area of the first wiring with respect to the second direction is greater than a cross-sectional area of the second wiring with respect to a direction in which the second wiring extends.

### Clause 5.

The semiconductor device according to clause 4, wherein the first signal wiring includes a third wiring electrically connected to the first wiring and the second gate electrode,
the cross-sectional area of the first wiring with respect to the second direction is greater than a cross-sectional area of the third wiring with respect to a direction in which the third wiring extends.

### Clause 6.

The semiconductor device according to any one of clauses 1 to 5, wherein the first electrode and the third electrode are exposed externally from the sealing resin.

### Clause 7.

The semiconductor device according to any one of clauses 1 to 6, wherein the first signal terminal is located opposite to the first electrode with respect to the first semiconductor element in the first direction.

### Clause 8.

The semiconductor device according to clause 7, further comprising a top terminal spaced apart from the first gate electrode and held in contact with the second electrode, wherein the top terminal is exposed externally from the sealing resin.

### Clause 9.

The semiconductor device according to any one of clauses 1 to 6, wherein the first signal terminal is located opposite to the second electrode with respect to the first semiconductor element in the first direction.

### Clause 10.

The semiconductor device according to claim 9, further comprising a bottom terminal spaced apart from the first gate electrode and held in contact with the second electrode, wherein the bottom terminal is exposed externally from the sealing resin.

### Clause 11.

The semiconductor device according to claim 9, further comprising a heat transfer layer having a first surface and a second surface facing opposite from each other in the first direction, the heat transfer layer being spaced apart from the first gate electrode,
wherein the first surface is exposed externally from the sealing resin,
the second electrode is conductively bonded to the second surface,
an entirety of the second surface overlaps with the first surface as viewed in the first direction.

### Clause 12.

The semiconductor device according to claim 11, wherein the heat transfer layer has a third side facing a same side as the second side surface in the first direction, the heat transfer layer being spaced apart from the second gate electrode,
the fourth electrode is conductively bonded to the third surface,
an entirety of the third surface overlaps with the first surface as viewed in the first direction.

### Clause 13.

The semiconductor device according to any one of clauses 9 to 12, further comprising an insulating coating layer, wherein the first signal wiring is exposed from the sealing resin,
the coating layer covers the first signal wiring.

### Clause 14.

The semiconductor device according to any one of clauses 9 to 12, wherein the first signal wiring is covered by the sealing resin.

### Clause 15.

The semiconductor device according to any one of clauses 9 to 14, further comprising:
a second signal terminal exposed externally from the sealing resin; and
second signal wiring electrically connecting the second and the fourth electrodes to the second signal terminal,
wherein the second signal terminal is located on a same side as the first signal terminal with respect to the first semiconductor element in the first direction.

### Clause 16.

A semiconductor module comprising:
a conductive member; and
a semiconductor device according to clause 7 or 8,
wherein the semiconductor device is conductively bonded to the conductive member,
the first electrode and the third electrode are located between the conductive member and the first signal terminal in the first direction.

### Clause 17.

A semiconductor module comprising:
a conductive member; and
a semiconductor device according to any one of clauses 9 to 15,
wherein the second electrode and the fourth electrode are located between the conductive member and the first signal terminal in the first direction.

### REFERENCE NUMERALS

A10, A20, A30, A40: Semiconductor device
B10: Semiconductor module 11: Substrate
12: First conductive member 121: First obverse surface
13: Second conductive member 131: Second obverse surface
151: First detection wiring layer
152: Second detection wiring layer
16: Third conductive member 161: Main portion
162: First connecting portion
163: Second connecting portion
21: First semiconductor element 17: Heat dissipation layer
212: Second electrode 211: First electrode
22: Second semiconductor element 213: First gate electrode
221: Third electrode 222: Fourth electrode
223: Second gate electrode 23: First signal terminal
24: First signal wiring 241: First top portion
243: First via portion 242: First bottom portion
24A: First wiring 24B: Second wiring
24C: Third wiring 25: Second signal terminal
26: Second signal wiring 261: Second top portion
262: Second bottom portion 263: Second via portion
28: Bottom terminal 27: Top terminal
31: Heat transfer layer 29: Conductive bonding layer
31A: First heat transfer layer
31B: Second heat transfer layer
311: First surface 312: Second surface
313: Third surface 32: Bonding layer
41: First input terminal 411: First mounting hole
42: Second input terminal 421: Second mounting hole
43: Output terminal 431: Third mounting hole
441: First gate terminal 442: Second gate terminal
451: First detection terminal
452: Second detection terminal
51: First wire 52: Second wire
53: Third wire 54: Fourth wire
55: Fifth wire 60: Mold resin
61: Top surface 62: Bottom surface
63: First side surface 64: Second side surface
71: Sealing resin 711: Top surface
712: Bottom surface 71A: First layer
71B: Second layer 72: Coating layer
z: First direction y: Second direction z: Third direction

1. A semiconductor device comprising:
a first semiconductor element including a first electrode, a second electrode and a first gate electrode both located on an opposite side to the first electrode in a first direction;
a second semiconductor element including a third electrode located on a same side as the first electrode with respect to the first semiconductor element in the first direction, a fourth electrode and a second gate electrode located on an opposite side to the third electrode in the first direction, the second semiconductor element being spaced apart from the first semiconductor element in a second direction perpendicular to the first direction;
a sealing resin covering at least a part of each of the first semiconductor element and the second semiconductor element;
a first signal terminal exposed externally from the sealing resin; and
a first signal wiring electrically connecting the first and the second gate electrodes to the first signal terminal,
wherein as viewed in the first direction, the first gate electrode has a first center,
as viewed in the first direction, the second gate electrode has a second center,
as viewed in the first direction, the first signal terminal has a third center,
a first straight line connecting the first center and the third center has a length of L1,
a second straight line connecting the second center and the third center has a length of L2,
a first path from the first center to the third center via the first signal wiring has a length of R1,
a second path from the second center to the third center via the first signal wiring has a length of R2,
R2/R1 is closer to 1 than is L2/L1.

2. The semiconductor device according to claim 1, wherein the length of the second path is equal to the length of the first path.

3. The semiconductor device according to claim 1, wherein the length of the second path is not smaller than 85% and not greater than 115% of the length of the first path.

4. The semiconductor device according to claim 1, wherein the first signal wiring includes a first wiring extending in the second direction and electrically connected to the first signal terminal, and a second wiring electrically connected to the first wiring and the first gate electrode,
a cross-sectional area of the first wiring with respect to the second direction is greater than a cross-sectional area of the second wiring with respect to a direction in which the second wiring extends.

5. The semiconductor device according to claim 4, wherein the first signal wiring includes a third wiring electrically connected to the first wiring and the second gate electrode,
the cross-sectional area of the first wiring with respect to the second direction is greater than a cross-sectional area of the third wiring with respect to a direction in which the third wiring extends.

6. The semiconductor device according to claim 1, wherein the first electrode and the third electrode are exposed externally from the sealing resin.

7. The semiconductor device according to claim 1, wherein the first signal terminal is located opposite to the first electrode with respect to the first semiconductor element in the first direction.

8. The semiconductor device according to claim 7, further comprising a top terminal spaced apart from the first gate electrode and held in contact with the second electrode,
wherein the top terminal is exposed externally from the sealing resin.

9. The semiconductor device according to claim 1, wherein the first signal terminal is located opposite to the second electrode with respect to the first semiconductor element in the first direction.

10. The semiconductor device according to claim 9, further comprising a bottom terminal spaced apart from the first gate electrode and held in contact with the second electrode,
wherein the bottom terminal is exposed externally from the sealing resin.

11. The semiconductor device according to claim 9, further comprising a heat transfer layer having a first surface and a second surface facing opposite from each other in the first direction, the heat transfer layer being spaced apart from the first gate electrode,
wherein the first surface is exposed externally from the sealing resin,
the second electrode is conductively bonded to the second surface,
an entirety of the second surface overlaps with the first surface as viewed in the first direction.

12. The semiconductor device according to claim 11, wherein the heat transfer layer has a third side facing a same side as the second side surface in the first direction, the heat transfer layer being spaced apart from the second gate electrode,
the fourth electrode is conductively bonded to the third surface,
an entirety of the third surface overlaps with the first surface as viewed in the first direction.

13. The semiconductor device according to claim 9, further comprising an insulating coating layer,
wherein the first signal wiring is exposed from the sealing resin,
the coating layer covers the first signal wiring.

14. The semiconductor device according to claim 9, wherein the first signal wiring is covered by the sealing resin.

15. The semiconductor device according to claim 9, further comprising:
a second signal terminal exposed externally from the sealing resin; and
a second signal wiring electrically connecting the second and the fourth electrodes to the second signal terminal,
wherein the second signal terminal is located on a same side as the first signal terminal with respect to the first semiconductor element in the first direction.

16. A semiconductor module comprising:
a conductive member; and
a semiconductor device according to claim 7,
wherein the semiconductor device is conductively bonded to the conductive member,
the first electrode and the third electrode are located between the conductive member and the first signal terminal in the first direction.

17. A semiconductor module comprising:
a conductive member; and
a semiconductor device according to claim 9,
wherein the second electrode and the fourth electrode are located between the conductive member and the first signal terminal in the first direction.
